(19) United States
(12) Patent Application Publication
(10) Pub. No.: US 2025/0385179 A1
(43) Pub. Date: Dec. 18, 2025

(54) THREE-DIMENSIONAL MEMORY DEVICES AND METHODS FOR FORMING THE SAME

(71) Applicant: YANGTZE MEMORY TECHNOLOGIES CO., LTD., Wuhan (CN)

(72) Inventors: Kuan Dong, Wuhan (CN); Hao Zhang, Wuhan (CN); Gang Zhang, Wuhan (CN); Zongliang Huo, Wuhan (CN)

(21) Appl. No.: 18/752,596

(22) Filed: Jun. 24, 2024

(30) Foreign Application Priority Data
Jun. 13, 2024 (CN) 202410763970.0

(51) Int. Cl. H01L 23/528; G11C 5/06; G11C 16/04; G11C 16/08; H01L 23/532; H10B 41/27; H10B 41/35; H10B 41/40; H10B 43/27; H10B 43/35; H10B 43/40

(52) U.S. Cl. CPC H01L 23/5283; G11C 5/063; G11C 16/0483; G11C 16/08; H01L 23/53295; H10B 41/27; H10B 41/35; H10B 41/40; H10B 43/27; H10B 43/35; H10B 43/40

(57) ABSTRACT

In certain aspects, a three-dimensional (3D) memory device includes a first stack structure including interleaved conductive layers and dielectric layers, a second stack structure over the first stack structure in a first direction and including interleaved conductive layers and dielectric layers, and a contact structure extending through the first stack structure and the second stack structure in the first direction and in contact with a first conductive layer of the conductive layers in the first stack structure and a second conductive layer of the conductive layers in the second stack structure.

### CROSS-REFERENCE TO RELATED APPLICATIONS

This application claims the benefit of priority to Chinese Application No. 202410763970.0, filed on Jun. 13, 2024, which is incorporated herein by reference in its entirety.

### BACKGROUND

The present disclosure relates to three-dimensional (3D) memory devices and fabrication methods thereof.

Planar memory cells are scaled to smaller sizes by improving process technology, circuit design, programming algorithm, and fabrication process. However, as feature sizes of the memory cells approach a lower limit, planar process and fabrication techniques become challenging and costly. As a result, memory density for planar memory cells approaches an upper limit.

A 3D memory architecture can address the density limitation in planar memory cells. The 3D memory architecture includes a memory array and peripheral devices for controlling signals to and from the memory array.

### SUMMARY

In one aspect, a 3D memory device includes a first stack structure including interleaved conductive layers and dielectric layers, a second stack structure over the first stack structure in a first direction and including interleaved conductive layers and dielectric layers, and a contact structure extending through the first stack structure and the second stack structure in the first direction and in contact with a first conductive layer of the conductive layers in the first stack structure and a second conductive layer of the conductive layers in the second stack structure.

In some implementations, each of the first conductive layer and the second conductive layer is at a same relative position in the first direction in the first stack structure and the second stack structure, respectively.

In some implementations, each of the first conductive layer and the second conductive layer includes a first portion in contact with the contact structure and a second portion not aligned with the first portion in the first direction.

In some implementations, each of the liner plugs includes a plurality of portions.

In some implementations, the contact structure is separated from the rest of the conductive layers in the first stack structure by a first spacer extending in the first direction and separated from the rest of the conductive layers in the second stack structure by a second spacer extending in the first direction.

In some implementations, the 3D memory device further includes a first select gate contact structure extending through the first stack structure and the second stack structure in the first direction, and a second select gate contact structure extending through the first stack structure and the second stack structure in the first direction. In some implementations, the first select gate contact structure is in contact with a third conductive layer of the conductive layers in the first stack structure and separated from all the conductive layers in the second stack structure, and the second select gate contact structure is in contact with a fourth conductive layer of the conductive layers in the second stack structure and separated from all the conductive layers in the first stack structure.

In some implementations, the third conductive layer is at an end position in the first direction in the first stack structure, and the fourth conductive layer is at an end position in the first direction in the second stack structure.

In some implementations, the contact structure, the first select gate contact structure, and the second select gate contact structure are disposed in a staircase region of the first stack structure and the second stack structure.

In some implementations, the first stack structure includes a first staircase structure including a first stair in the staircase region, and the second stack structure includes a second staircase structure including a second stair in the staircase region. In some implementations, the contact structure is in contact with part of the first conductive layer at the first stair and part of the second conductive layer at the second stair, and the first and second stairs are at a same level with respect to the first and second staircase structures, respectively.

In some implementations, the first stack structure includes a first staircase structure including a third stair in the staircase region, and the second stack structure includes a second staircase structure including a fourth stair in the staircase region. In some implementations, the first select gate contact structure is in contact with part of the third conductive layer at the third stair, and the second select gate contact structure is in contact with part of the fourth conductive layer at the fourth stair. In some implementations, the third and fourth stairs are at a same level with respect to the first and second staircase structures, respectively.

In some implementations, the 3D memory device further includes a first semiconductor layer, a second semiconductor layer between the first stack structure and the second stack structure in the first direction, a first channel structure extending through the first stack structure in the first direction and in contact with the first semiconductor layer, and a second channel structure extending through the second stack structure in the first direction and in contact with the second semiconductor layer.

In some implementations, the contact structure includes a first portion extending through the first stack structure and in contact with the first conductive layer, and a second portion extending through the second stack structure and the second semiconductor layer and in contact with the second conductive layer.

In some implementations, the 3D memory device further includes a first bit line extending in a second direction perpendicular to the first direction and in contact with the first channel structure, and a second bit line extending in the second direction and in contact with the second channel structure. In some implementations, the first conductive layer extends in a third direction perpendicular to the first and second directions and is in contact with the first channel structure, and the second conductive layer extends in the third direction and is in contact with the second channel structure.

In some implementations, the 3D memory device further includes a first bonding contact and a second bonding contact. In some implementations, the first bonding contact and the second bonding contact are between the first stack structure and the second stack structure in the first direction and in contact with one another.

In some implementations, the contact structure includes a third bonding contact and a fourth bonding contact in contact with one another.

In another aspect, a method for forming a 3D memory device is disclosed. A first stack structure including interleaved conductive layers and dielectric layers is formed. A second stack structure over the first stack structure and including interleaved conductive layers and dielectric layers is formed. A contact structure extending through the first stack structure and the second stack structure and in contact with a first conductive layer of the conductive layers in the first stack structure and a second conductive layer of the conductive layers in the second stack structure is formed.

In some implementations, to form the contact structure, a first portion of the contact structure extending through the first stack structure and in contact with the first conductive layer in the first stack structure is formed, and a second portion of the contact structure extending through the second stack structure and in contact with the second conductive layer in the second stack structure is formed. In some implementations, the second portion of the contact structure is in contact with the first portion of the contact structure.

In some implementations, to form the first portion or the second portion of the contact structure, a dielectric stack including interleaved first dielectric layers and second dielectric layers is formed, sacrificial layers are formed on the dielectric stack, an opening extending through the dielectric stack is formed, the second dielectric layers and the sacrificial layers are replaced with conductive layers, and the first portion or the second portion of the contact structure are formed in the opening.

In some implementations, a spacer is formed on a part of a sidewall of the opening. In some implementations, the first portion or the second portion of the contact structure is formed in contact with only one of the conductive layers.

In some implementations, to form the sacrificial layers on the dielectric stack, a staircase structure including stairs is formed in the dielectric stack, and the sacrificial layers are formed on a topmost layer of each stair of the staircase structure.

In some implementations, each of the first conductive layer and the second conductive layer is at a same relative position in the first stack structure and the second stack structure, respectively.

In some implementations, a semiconductor layer is formed over the first stack structure, and the second stack structure is formed over the semiconductor layer. In some implementations, the contact structure extends through the first stack structure, the semiconductor layer, and the second stack structure.

In some implementations, a first select gate contact structure extending through the first stack structure and the second stack structure is formed, and a second select gate contact structure extending through the first stack structure and the second stack structure is formed. In some implementations, the first select gate contact structure is in contact with a third conductive layer of the conductive layers in the first stack structure and separated from all the conductive layers in the second stack structure. In some implementations, the second select gate contact structure is in contact with a fourth conductive layer of the conductive layers in the second stack structure and separated from all the conductive layers in the first stack structure.

In some implementations, to form the first and second select gate contact structures, a first portion of the first select gate contact structure extending through the first stack structure and in contact with the third conductive layer in the first stack structure, and a first portion of the second select gate contact structure extending through the first stack structure and separated from all the conductive layers in the first stack structure are formed, and a second portion of the first select gate contact structure extending through the second stack structure and separated from all the conductive layers in the second stack structure, and a second portion of the second select gate contact structure extending through the second stack structure and in contact with the fourth conductive layer in the second stack structure are formed.

In still another aspect, a memory device includes an array of memory cells arranged in a first block and a second block, a first source line coupled to the first block, and a second source line coupled to the second block, a first bit line coupled to the first block, and a second bit line coupled to the second block, a first word line coupled to the first block, and a second word line coupled to the second block, a first select gate line coupled to the first block, and a second select gate line coupled to the second block, and peripheral circuits configured to operate the array of memory cells. The first word line is coupled to the second word line. The peripheral circuits include a same word line string driver coupled to the first block and the second block through the first word line and the second word line, a first select gate string driver coupled to the first block through the first select gate line, and a second select gate string driver coupled to the second block through the second select gate line.

In some implementations, the first source line is separated from the second source line, and the first bit line is separated from the second bit line.

In some implementations, the first source line is coupled to the second source line, and the first bit line is coupled to the second bit line.

In some implementations, the peripheral circuits are configured to erase the first block using at least the first select gate string driver and the word line string driver, and erase the second block using at least the second select gate string driver and the word line string driver.

### BRIEF DESCRIPTION OF THE DRAWINGS

The accompanying drawings, which are incorporated herein and form a part of the specification, illustrate aspects of the present disclosure and, together with the description, further serve to explain the principles of the present disclosure and to enable a person skilled in the pertinent art to make and use the present disclosure.

FIG. 1A illustrates a schematic circuit diagram of a memory device, according to some aspects of the present disclosure.

FIG. 1B illustrates a block diagram of the memory device in FIG. 1A including a memory cell array and peripheral circuits, according to some aspects of the present disclosure.

FIGS. 2A and 2B illustrate a cross-sectional side view of a 3D memory device having contact structures, according to some aspects of the present disclosure.

FIG. 3 illustrates a cross-sectional side view of another 3D memory device having contact structures, according to some aspects of the present disclosure.

FIGS. 4A-4N illustrate a fabrication process for forming a 3D memory device having contact structures, according to some aspects of the present disclosure.

FIG. 5 is a flowchart of a method for forming a 3D memory device having contact structures, according to some aspects of the present disclosure.

FIG. 6 is a flowchart of a method for forming contact structure in a 3D memory device, according to some aspects of the present disclosure.

FIG. 7 illustrates a block diagram of an exemplary system having a 3D memory device, according to some aspects of the present disclosure.

FIG. 8A illustrates a diagram of an exemplary memory card having a 3D memory device, according to some aspects of the present disclosure.

FIG. 8B illustrates a diagram of an exemplary solid-state drive (SSD) having a 3D memory device, according to some aspects of the present disclosure.

The present disclosure will be described with reference to the accompanying drawings.

### DETAILED DESCRIPTION

Although specific configurations and arrangements are discussed, it should be understood that this is done for illustrative purposes only. As such, other configurations and arrangements can be used without departing from the scope of the present disclosure. Also, the present disclosure can also be employed in a variety of other applications. Functional and structural features as described in the present disclosures can be combined, adjusted, and modified with one another and in ways not specifically depicted in the drawings, such that these combinations, adjustments, and modifications are within the scope of the present disclosure.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context. In addition, the term “based on” may be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the term “substrate” refers to a material onto which subsequent material layers are added. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “layer” refers to a material portion including a region with a thickness. A layer can extend over the entirety of an underlying or overlying structure or may have an extent less than the extent of an underlying or overlying structure. Further, a layer can be a region of a homogeneous or inhomogeneous continuous structure that has a thickness less than the thickness of the continuous structure. For example, a layer can be located between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layers thereupon, thereabove, and/or therebelow. A layer can include multiple layers. For example, an interconnect layer can include one or more conductors and contact layers (in which interconnect lines and/or vertical interconnects are formed) and one or more dielectric layers.

In some 3D memory devices, such as 3D NAND memory devices, memory cells for storing data are vertically stacked through a stack structure (e.g., a memory stack) in vertical channel structures. 3D memory devices usually include staircase structures formed on one or more sides (edges), or at the center, of the stacked storage structure for purposes, such as word line pick-up/fan-out, using word/gate line contact structures landed onto different steps/levels of a staircase structure. As the number of vertically stacked levels/layers of memory cells continues increasing, the process difficulty of etching deep holes for forming the word line contact structures also increases significantly, and the critical dimensions of the holes need to increase as well, thereby reducing the effective areas available for memory cells. Moreover, the increased number of word line contact structures requires an increased number of word line string drivers, which occupy a significant portion of effective areas available for memory cells as well. On the other hand, the increased number of levels/layers of memory cells also increases the depth of a single channel structure that extends through all the levels/layers in the vertical direction, thereby reducing the channel current that is essential for read operations due to the increased channel resistance. All these challenges obstruct the increase of memory cell density and complicate the manufacturing process of memory devices.

To address one or more of the aforementioned issues, the present disclosure introduces a novel type of contact structure that can extend through multiple memory stacks (a.k.a., memory decks) and connect to only certain word/gate line(s) in these memory stacks. In some implementations, channel structures are formed in each memory stack, as opposed to extending through multiple memory stacks, such that the channel current can be maintained at the desired level. In some implementations, by designating certain novel contact structures to connect to the drain select gate (DSG) transistors and/or source select gate (SSG) transistors of certain memory stack(s), a single word line string driver can control multiple word lines in different memory stacks, thereby reducing the number of word line string drivers and their occupied areas for driving the same number of memory cells. As a result, the present disclosure can effectively increase the memory cell density and reduce fabrication complexity and cost.

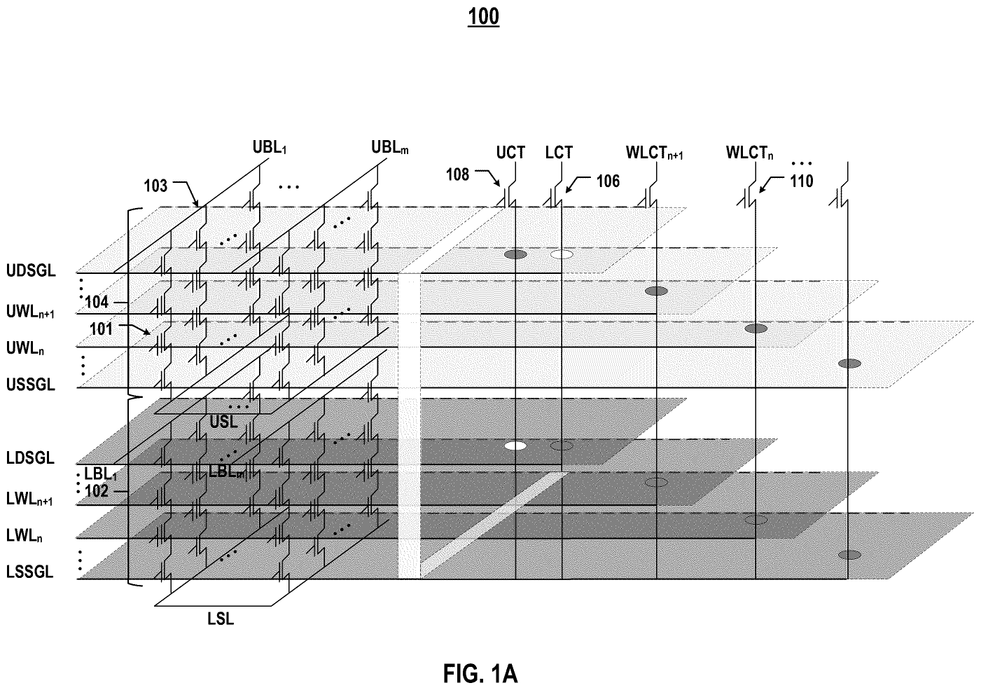

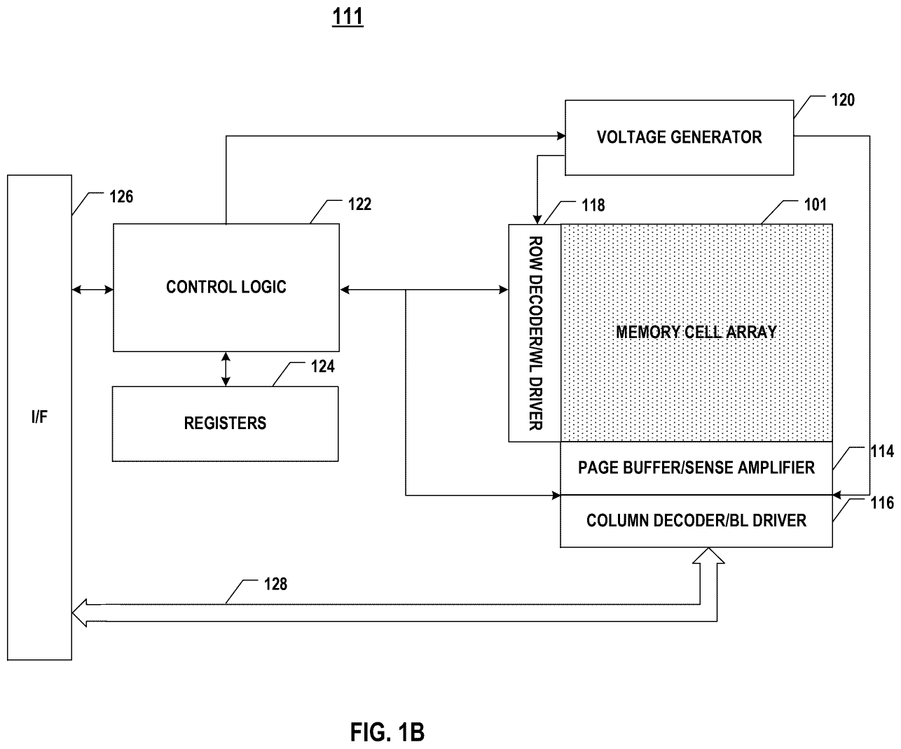

FIG. 1A illustrates a schematic circuit diagram of a memory device 100, according to some aspects of the present disclosure. Memory device 100 can be, for example, a 3D NAND memory device, and include an array of memory cells 101. Array of memory cells 101 can be a NAND Flash memory cell array in which memory cells 101 are provided in the form of an array of NAND memory strings 103 each extending vertically above a substrate (not shown). In some implementations, each NAND memory string 103 includes a plurality of memory cells 101 coupled in series and stacked vertically. Each memory cell 101 can hold a continuous, analog value, such as an electrical voltage or charge, which depends on the number of electrons trapped within a region of memory cell 101. Each memory cell 101 can be either a floating gate type of memory cell including a floating-gate transistor or a charge trap type of memory cell including a charge-trap transistor.

Array of memory cells 101 can be arranged in multiple blocks, including a first block 102 and a second block 104, each of which is a basic data unit for erase operations, i.e., all memory cells 101 on a same block 102 or 104 are erased at the same time. Memory device 100 can further include source lines (SL) each coupled to a respective one of the blocks. For example, a first source line (LSL) may be coupled to first block 102, and a second source line (USL) may be coupled to second block 104. That is, each block can share a common source line coupled to the array common source (ACS) of NAND memory strings 103 in the respective block. To erase memory cells 101 in a select block 102 or 104, the source line coupled to select block 102 or 104 can be biased with an erase voltage (Vers), such as a high positive bias voltage (e.g., 20 V or more).

As shown in FIG. 1A, memory device 100 can also include one or more bit lines (BLs) coupled to each block. In some implementations, the drain of each NAND memory string 103 is coupled to a respective bit line from which data can be read or written via an output bus (not shown). For example, one or more first bit lines (LBL₁, . . . , LBLₘ) may be coupled to first block 102, and one or more second bit lines (UBL₁, . . . , UBLₘ) may be coupled to second block 104. As shown in FIG. 1A, the first source line is (LSL) separated from second source line (USL), and the first bit line(s) are separated from the second bit line(s), such that that the sources and the drains of first block 102 and second block 104 can be separately and individually controlled. It is understood that in some examples, the first source line (LSL) may be coupled to the second source line (USL), and a first bit line (one of LBL₁, . . . , LBLₘ) may be coupled to a corresponding second bit line (corresponding one of UBL₁, . . . , UBLₘ), such that that the sources and the drains of first block 102 and second block 104 may be controlled together at the same time.

As shown in FIG. 1A, memory device 100 can further include word lines (WLs) coupled to each block. Memory cells 101 of adjacent NAND memory strings 103 can be coupled through the word lines that select which row of memory cells 101 is affected by read and program operations. In some implementations, each word line is coupled to a plurality of memory cells 101. Each word line can include a plurality of control gates (gate electrodes) at each memory cell 101 and a gate line coupling the control gates. For example, first word lines (LWLₙ, WLₙ₊₁, . . . ) may be coupled to first block 102, and second word lines (UWLₙ, ULₙ₊₁, . . . ) may be coupled to second block 104.

As shown in FIG. 1A, each NAND memory string 103 can also include a source select gate (SSG) transistor (a.k.a., bottom select gate (BSG) transistor) at its source end and a drain select gate (DSG) transistor (a.k.a., top select gate (TSG) transistor) at its drain end. The SSG transistor and DSG transistor can be configured to activate select NAND memory strings 103 (columns of the array) during read and program operations. As shown in FIG. 1A, memory device 100 can further include select gate lines (SGLs) coupled to each block. In some implementations, each NAND memory string 103 is configured to be selected or deselected by applying a select voltage (e.g., a positive voltage greater than the threshold voltage of the DSG transistor) or a deselect voltage (e.g., the ground voltage) to the gate of respective DSG transistor through one or more DSG lines (DSGLs) and/or by applying a select voltage (e.g., a positive voltage greater than the threshold voltage of the SSG transistor) or a deselect voltage (e.g., the ground voltage) to the gate of respective SSG transistor through one or more SSG lines (SSGLs). In one example, a first drain select gate line (LDSGL) may be coupled to first block 102, and a second drain select gate line (UDSGL) may be coupled to second block 104. In another example, a first source select gate line (LSSGL) may be coupled to first block 102, and a second source select gate line (USSGL) may be coupled to second block 104.

FIG. 1B illustrates a block diagram of memory device 100 in FIG. 1A including array of memory cells 101 and peripheral circuits 111, according to some aspects of the present disclosure. Peripheral circuits 111 can be coupled to array of memory cells 101 through the bit lines, word lines, source lines, SSG lines, and DSG lines. Peripheral circuits 111 can include any suitable analog, digital, and mixed-signal circuits for facilitating the operations of array of memory cells 101 by applying and sensing voltage signals and/or current signals to and from each select memory cell 101 through the bit lines, word lines, source lines, SSG lines, and DSG lines. Peripheral circuits 111 can include various types of peripheral circuits formed using metal-oxide-semiconductor (MOS) technologies. For example, FIG. 1B illustrates some exemplary peripheral circuits including a page buffer/sense amplifier 114, a column decoder/bit line driver 116, a row decoder/word line driver 118, a voltage generator 120, control logic 122, registers 124, an interface (I/F) 126, and a data bus 128. It is understood that in some examples, additional peripheral circuits not shown in FIG. 1B may be included as well.

Page buffer/sense amplifier 114 can be configured to sense (read) and program (write) data from and to array of memory cells 101 according to the control signals from control logic 122. In one example, page buffer/sense amplifier 114 may store one or more pages of program data to be programmed. In another example, page buffer/sense amplifier 114 may verify programmed select memory cells 101 in each program/verify cycle in a program operation to ensure that the data has been properly programmed into memory cells 101 coupled to the select word lines. In still another example, page buffer/sense amplifier 114 may also sense the low power signals from the bit line that represents a data bit stored in memory cell 101 and amplify the small voltage swing to recognizable logic levels in a read operation.

Column decoder/bit line driver 116 can be configured to be controlled by control logic 122 and select one or more NAND memory strings 103 by applying bit line voltages generated from voltage generator 120. Row decoder/word line driver 118 can be configured to be controlled by control logic 122 and select/deselect blocks 102 and 104 and select/deselect the word lines of block 102 or 104. Row decoder/word line driver 118 can be further configured to drive the word lines using word line voltages generated from voltage generator 120. In some implementations, row decoder/word line driver 118 can also select/deselect and drive the SSG lines and DSG lines as well. Voltage generator 120 can be configured to be controlled by control logic 122 and generate the word line voltages (e.g., read voltage, program voltage, channel pass voltage, local voltage, verify voltage, etc.), bit line voltages, and source line voltages to be supplied to array of memory cells 101.

Control logic 122 can be coupled to each peripheral circuit described above and configured to control the operations of each peripheral circuit. Registers 124 can be coupled to control logic 122 and include status registers, command registers, and address registers for storing status information, command operation codes (OP codes), and command addresses for controlling the operations of each peripheral circuit. Interface 126 can be coupled to control logic 122 and act as a control buffer to buffer and relay control commands received from a memory controller (not shown) and/or a host (not shown) to control logic 122 and status information received from control logic 122 to the memory controller and/or the host. Interface 126 can also be coupled to column decoder/bit line driver 116 via data bus 128 and act as a data input/output (I/O) interface and a data buffer to buffer and relay the data to and from array of memory cells 101.

Consistent with the scope of the present disclosure, row decoder/word line driver 118 can include a word line driver (not shown), a decoder (not shown), a plurality of word line string drivers (110 in FIG. 1A, e.g., driving transistors) respectively coupled to the word lines, and a plurality of select gate string drivers (106 and 108 in FIG. 1A, e.g., driving transistors) respectively coupled to the select gate lines. In some implementations, as shown in FIG. 1A, word line string driver 110 is coupled to a respective word line in each of the blocks through a word line contact structure (WLCT). For example, a word line string driver 110 is coupled to both a first word line (LWLₙ) in first block 102 and a second word line (UWLₙ) in second block 104 through a word line contact structure (WLCTₙ), and another word line string driver 110 is coupled to both another first word line (LWLₙ₊₁) in first block 102 and another second word line (UWLₙ₊₁) in second block 104 through another word line contact structure (WLCTₙ₊₁). That is, a same word line string driver 110 can be coupled to first block 102 and second block 104 through the first word line and the second word line. It is understood that although two blocks are shown in FIGS. 1A, in some examples, the same word line string driver 110 may be coupled to three or more blocks through three or more word lines.

In some implementations, as shown in FIG. 1A, each drain select gate string driver 106 or 108 is coupled to a respective drain select gate line in a respective block through a respective drain select gate contact structure (CT). For example, a first drain select gate string driver 106 may be coupled to first drain select gate line (LDSGL) in first block 102, but not second drain select gate line (UDSGL) in second block 104, whereas a second drain select gate string driver 108 may be coupled to second drain select gate line (UDSGL) in second block 104, but not first drain select gate line (LDSGL) in first block 102. That is, a first drain select gate string driver can be coupled to the first block through the first drain select gate line, while a second drain select gate string driver can be coupled to the second block through the second drain select gate line. It is understood that although two blocks are shown in FIGS. 1A, in some examples, additional drain select gate string driver can be coupled to additional block through additional drain select gate line. It is also understood that although drain select gate string drivers and drain select gate lines are shown in FIG. 1A, in some examples, source select gate string drivers and source select gate lines may be configured in the same manner. In other words, a first select gate string driver (a first drain select gate string driver and/or a first source select gate string driver) can be coupled to the first block through the first select gate line (the first drain select gate line and/or the first source select gate line), and a second select gate string driver (a second drain select gate string driver and/or a second source select gate string driver) can be coupled to the second block through the second select gate line (the second drain select gate line and/or the second source select gate line).

As a result, word lines from different blocks 102 and 104 can be driven by the same word line string driver 110 in a multiplexing manner, which is controlled by individual select gate string driver 106 and/or 108 for each block 102 or 104, thereby reducing the total number of word line string drivers 110 needed in memory device 100 and their occupied areas. In some implementations, peripheral circuits 111 are configured to erase first block 102 using at least first drain select gate string driver 106 and word line string drivers 110, and erase second block 104 using at least second drain select gate string driver 108 and the same word line string drivers 110.

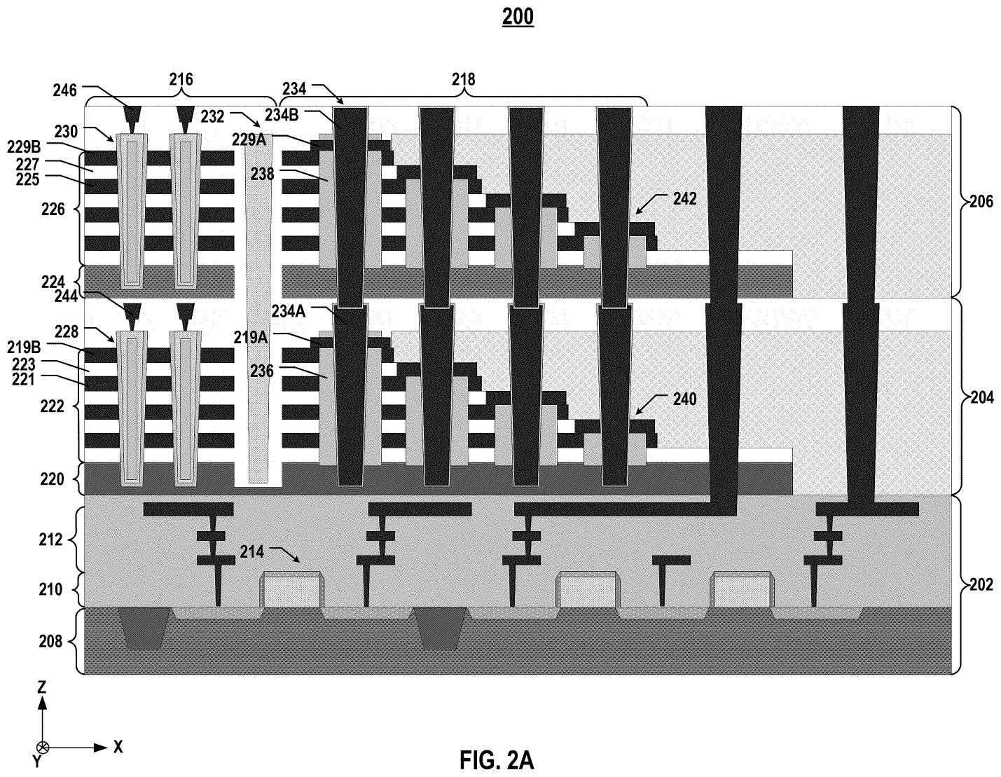

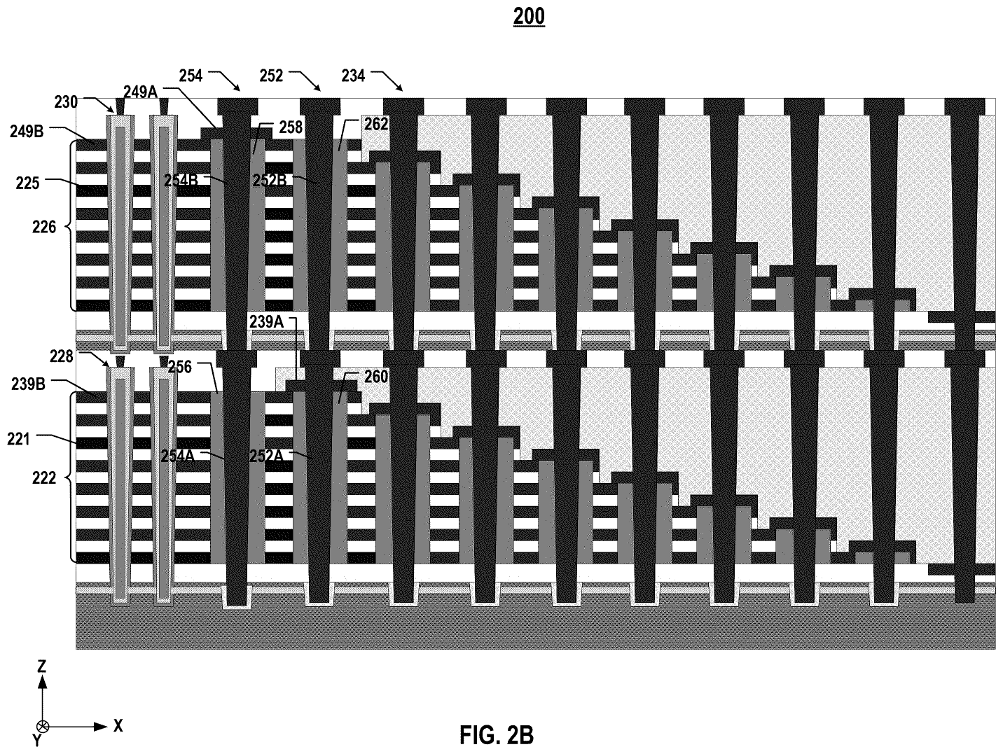

FIGS. 2A and 2B illustrate a cross-sectional side view of a 3D memory device 200 having contact structures, according to some aspects of the present disclosure. As shown in FIG. 2A, 3D memory device 200 can include a first semiconductor structure 202, a second semiconductor structure 204 over first semiconductor structure 202, and a third semiconductor structure 206 over second semiconductor structure 204. In other words, 3D memory device 200 includes semiconductor structures 202, 204 and 206, which are stacked over one another in different planes in the vertical direction (e.g., the z-direction in FIG. 2A).

It is noted that x-, y-, and z-axes are added in FIG. 2A to further illustrate the spatial relationships of the components of a semiconductor device. A substrate of a semiconductor device, e.g., 3D memory device 200, includes two lateral surfaces (e.g., a top surface and a bottom surface) extending laterally in the x- and y-direction (the lateral direction or horizontal direction). As used herein, whether one component (e.g., a layer or a device) is “on,” “above,” “over,” “below” “beneath,” or “underneath” another component (e.g., a layer or a device) of a semiconductor device is determined relative to the substrate of the semiconductor device in the z-direction (the vertical direction or thickness direction) when the substrate is positioned in the lowest plane of the semiconductor device in the z-direction. The x- and y-directions are two orthogonal (perpendicular) directions in the wafer plane. The x-direction is the word line direction of 3D memory device 200, and the y-direction is the bit line direction of 3D memory device 200. The same notion for describing the spatial relationships is applied throughout the present disclosure.

As shown in FIG. 2A, first semiconductor structure 202 can include a semiconductor layer 208 having semiconductor materials. In some implementations, semiconductor layer 208 is a silicon substrate having single crystalline silicon. First semiconductor structure 202 can also include a device layer 210 above and in contact with semiconductor layer 208. In some implementations, device layer 210 includes peripheral circuits 214 having a plurality of transistors in contact with semiconductor layer 208. Trench isolations (e.g., shallow trench isolations (STIs)) and doped regions (e.g., wells, sources, and drains of the transistors) can be formed on or in semiconductor layer 208 as well. Peripheral circuits 214 (a.k.a. control and sensing circuits) can include any suitable digital, analog, and/or mixed-signal circuits used for facilitating the operations of the memory cell array in 3D memory device 200. For example, peripheral circuits 214 can include one or more of a page buffer, a decoder (e.g., a row decoder and a column decoder), a sense amplifier, a driver (e.g., a word line driver), an input/output (I/O) circuit, a charge pump, a voltage source or generator, a current or voltage reference, any portions (e.g., a sub-circuit) of the functional circuits mentioned above, or any active or passive components of the circuit (e.g., transistors, diodes, resistors, or capacitors). Peripheral circuits 214 can use complementary metal-oxide-semiconductor (CMOS) technology, e.g., which can be implemented with logic processes in any suitable technology nodes. Peripheral circuits 214 may include word line string drivers 110 and select gate string drivers 106 and 108 in FIG. 1A.

In some implementations, first semiconductor structure 202 further includes an interconnect layer 212 above device layer 210 to transfer electrical signals to and from peripheral circuits 214. Interconnect layer 212 can include a plurality of interconnects, including lateral lines and vias. As used herein, the term “interconnects” can broadly include any suitable types of interconnects, such as middle-end-of-line (MEOL) interconnects and back-end-of-line (BEOL) interconnects. The interconnects in interconnect layer 212 can be coupled to the transistors of peripheral circuits 214 in device layer 210. Interconnect layer 212 can further include one or more interlayer dielectric (ILD) layers (also known as “intermetal dielectric (IMD) layers”) in which the lateral lines and vias can form. That is, interconnect layer 212 can include lateral lines and vias in multiple ILD layers. The interconnects in interconnect layer 212 can include conductive materials including, but not limited to, tungsten (W), cobalt (Co), copper (Cu), aluminum (Al), silicides, or any combination thereof. The ILD layers in interconnect layer 212 can include dielectric materials including, but not limited to, silicon oxide, silicon nitride, silicon oxynitride, low dielectric constant (low-k) dielectrics, or any combination thereof.

Second semiconductor structure 204 can be formed on first semiconductor structure 202. As shown in FIG. 2A, second semiconductor structure 204 can include a semiconductor layer 220 having semiconductor materials. Semiconductor layer 220 may be an example of part of LSL in FIG. 1A. In some implementations, semiconductor layer 220 is a layer of single crystalline silicon transferred from a silicon substrate or a silicon-in-insulator (SOI) substrate and attached to the top surface of first semiconductor structure 202 by transfer bonding. In some implementations, semiconductor layer 220 is a layer of polysilicon deposited on the top surface of first semiconductor structure 202. Second semiconductor structure 204 can also include a stack structure 222, e.g., a memory stack, on semiconductor layer 220. Stack structure 222 can include interleaved conductive layers 221 and dielectric layers 223. The number of the pairs of conductive layers 221 and dielectric layers 223 in stack structure 222 can determine the number of memory cells in second semiconductor structure 204. Conductive layer 221 can include conductive materials including, but not limited to, W, Co, Cu, Al, polysilicon, doped silicon, silicides, or any combination thereof. In some implementations, each conductive layer 221 includes a metal layer, such as a tungsten layer. In some implementations, each conductive layer 221 includes a doped polysilicon layer. Each conductive layer 221 can include control gates surrounding the memory cells, the gates of DSG transistors, or the gates of SSG transistors, and can extend laterally as DSG line(s) at the top of stack structure 222 (an end position in the z-direction), SSG line(s) at the bottom of stack structure 222 (another end position in the z-direction)), or word lines between the DSG line(s) and SSG line(s). The word lines, DSG line(s), and SSG line(s) in second semiconductor structure 204 may be examples of LWL, LDSGL, and LSSGL in FIG. 1A.

In some implementations, stack structure 222 is divided into a memory array region 216 in which memory cell array is formed, and a staircase region 218 in which a staircase structure 240 is formed for word line pick-up/fan-out. As shown in FIG. 2A, second semiconductor structure 204 can include an array of NAND memory strings in which memory cells are formed in memory array region 216 of stack structure 222. The NAND memory strings may be examples of NAND memory strings 103 in FIG. 1A. Each NAND memory string can include a channel structure 228 extending vertically (in the z-direction) through stack structure 222 and in contact with semiconductor layer 220. In some implementations, channel structure 228 includes a channel hole filled with semiconductor material(s) (e.g., as a semiconductor channel) and dielectric material(s) (e.g., as a memory film). In some implementations, the semiconductor channel includes silicon, such as polysilicon. In some implementations, the memory film is a composite dielectric layer including a tunneling layer, a storage layer (also known as a “charge trap/storage layer”), and a blocking layer. Channel structure 228 can have a cylinder shape (e.g., a pillar shape). The semiconductor channel, tunneling layer, storage layer, blocking layer are arranged radially from the center toward the outer surface of the pillar in this order, according to some implementations. The tunneling layer can include silicon oxide, silicon oxynitride, or any combination thereof. The storage layer can include silicon nitride, silicon oxynitride, silicon, or any combination thereof. The blocking layer can include silicon oxide, silicon oxynitride, high-k dielectrics, or any combination thereof. In one example, the memory film may include a composite layer of silicon oxide/silicon oxynitride/silicon oxide (ONO).

As shown in FIG. 2A, second semiconductor structure 204 can further include bit lines 244 each extending in the bit line direction (the y-direction) and in contact with channel structure 228. Bit lines 244 can include conductive materials including, but not limited to, W, Co, Cu, Al, polysilicon, doped silicon, silicides, or any combination thereof.

As shown in FIG. 2A, second semiconductor structure 204 can include staircase structure 240 in staircase region 218 of stack structure 222, which includes a plurality of stairs. Each stair (level) of staircase structure 240 can include one or more conductor/dielectric layer pairs, each including conductive layer 221 and dielectric layer 223. The top layer in each stair of staircase structure 240 can be conductive layer 221 for interconnection in the vertical direction (the z-direction). In some implementations, each two adjacent stairs of staircase structure 240 are offset by a same distance in the vertical direction and a same distance in the lateral direction (e.g., the x-direction). For each two adjacent stairs of staircase structure 240, the lower stair (and conductive layer 221 and dielectric layer 223 therein) that is closer to semiconductor layer 220 can extend laterally further than the upper stair (and conductive layer 221 and dielectric layer 223 therein), thereby forming a “contact area” on the lower stair for interconnection in the vertical direction (the z-direction).

Third semiconductor structure 206 can be formed on second semiconductor structure 204. As shown in FIG. 2A, third semiconductor structure 206 can include a semiconductor layer 224 having semiconductor materials. Semiconductor layer 224 may be an example of part of USL in FIG. 1A. In some implementations, semiconductor layer 224 is a layer of single crystalline silicon transferred from a silicon substrate or an SOI substrate and attached to the top surface of second semiconductor structure 204 by transfer bonding. In some implementations, semiconductor layer 224 is a layer of polysilicon deposited on the top surface of second semiconductor structure 204. Third semiconductor structure 206 can also include a stack structure 226, e.g., a memory stack, on semiconductor layer 224. In some implementations, semiconductor layer 224 is disposed between stack structure 222 of second semiconductor structure 204 and stack structure 226 of third semiconductor structure 206 in the vertical direction (the z-direction). In some implementations, stack structure 222 of second semiconductor structure 204 is disposed over stack structure 226 of third semiconductor structure 206 in the vertical direction (the z-direction). Similar to stack structure 222, stack structure 226 can include interleaved conductive layers 225 and dielectric layers 227. The number of the pairs of conductive layers 225 and dielectric layers 227 in stack structure 226 can determine the number of memory cells in third semiconductor structure 206. Conductive layer 225 can include conductive materials including, but not limited to, W, Co, Cu, Al, polysilicon, doped silicon, silicides, or any combination thereof. In some implementations, each conductive layer 225 includes a metal layer, such as a tungsten layer. In some implementations, each conductive layer 225 includes a doped polysilicon layer. Each conductive layer 225 can include control gates surrounding the memory cells, the gates of DSG transistors, or the gates of SSG transistors, and can extend laterally as DSG line(s) at the top of stack structure 226 (an end position in the z-direction), SSG line(s) at the bottom of stack structure 226 (another end position in the z-direction)), or word lines between the DSG line(s) and SSG line(s). The word lines, DSG line(s), and SSG line(s) in third semiconductor structure 206 may be examples of UWL, UDSGL, and USSGL in FIG. 1A.

In some implementations, similar to stack structure 222, stack structure 226 is also divided into memory array region 216 in which a memory cell array is formed, and staircase region 218 in which a staircase structure 242 is formed for word line pick-up/fan-out. As shown in FIG. 2A, third semiconductor structure 206 can include an array of NAND memory strings in which memory cells are formed in memory array region 216 of stack structure 226. The NAND memory strings may be examples of NAND memory strings 103 in FIG. 1A. Each NAND memory string can include a channel structure 230 extending vertically (in the z-direction) through stack structure 226 and in contact with semiconductor layer 224. In some implementations, channel structure 230 includes a channel hole filled with semiconductor material(s) (e.g., as a semiconductor channel) and dielectric material(s) (e.g., as a memory film). In some implementations, the semiconductor channel includes silicon, such as polysilicon. In some implementations, the memory film is a composite dielectric layer including a tunneling layer, a storage layer (also known as a “charge trap/storage layer”), and a blocking layer. Channel structure 230 can have a cylinder shape (e.g., a pillar shape). The semiconductor channel, tunneling layer, storage layer, and blocking layer are arranged radially from the center toward the outer surface of the pillar in this order, according to some implementations. The tunneling layer can include silicon oxide, silicon oxynitride, or any combination thereof. The storage layer can include silicon nitride, silicon oxynitride, silicon, or any combination thereof. The blocking layer can include silicon oxide, silicon oxynitride, high-k dielectrics, or any combination thereof. In one example, the memory film may include a composite layer of ONO.

As shown in FIG. 2A, third semiconductor structure 206 can further include bit lines 246 each extending in the bit line direction (the y-direction) and in contact with channel structure 230. Bit lines 246 can include conductive materials including, but not limited to, W, Co, Cu, Al, polysilicon, doped silicon, silicides, or any combination thereof.

As shown in FIG. 2A, third semiconductor structure 206 can include staircase structure 242 in staircase region 218 of stack structure 226, which includes a plurality of stairs. Each stair (level) of staircase structure 242 can include one or more conductor/dielectric layer pairs, each including conductive layer 225 and dielectric layer 227. The top layer in each stair of staircase structure 242 can be conductive layer 225 for interconnection in the vertical direction (the z-direction). In some implementations, each two adjacent stairs of staircase structure 242 are offset by a same distance in the vertical direction and a same distance in the lateral direction (e.g., the x-direction). For each two adjacent stairs of staircase structure 242, the lower stair (and conductive layer 225 and dielectric layer 227 therein) that is closer to semiconductor layer 224 can extend laterally further than the upper stair (and conductive layer 225 and dielectric layer 227 therein), thereby forming a “contact area” on the lower stair for interconnection in the vertical direction (the z-direction).

As shown in FIG. 2A, 3D memory device 200 can further include a slit structure 232 (e.g., a gate line slit (GLS)) extending through stack structure 226, semiconductor layer 224, and stack structure 222, and in contact with semiconductor layer 220 in the vertical direction (the z-direction). In some implementations, slit structure 232 includes a conductor (e.g., W and/or titanium nitride (TiN)) surrounded by a dielectric spacer (e.g., silicon oxide), such that the conductor can serve as the source interconnect for channel structures 228 and 230, and the dielectric spacer can separate the array of NAND memory strings in stack structures 222 and 226 into different regions (e.g., fingers and/or blocks). In some implementations, slit structure 232 is filled with a dielectric material (e.g., silicon oxide) to separate the array of NAND memory strings in stack structures 222 and 226 into different regions (e.g., fingers and/or blocks). It is understood that although a single slit structure 232 extends through both stack structure 226 and stack structure 222, as shown in FIG. 2A, it is understood that in some examples (not shown), each semiconductor structure 204 or 206 may include a separate slit structure extending through a respective stack structure 222 or 226 and in contact with a respective semiconductor layer 220 or 224.

As shown in FIG. 2A, 3D memory device 200 can further include word line contact structures 234 (referred to herein as “contact structures” as well) in staircase region 218 of stack structures 222 and 226. Word line contact structures 234 may be examples of WLCT in FIG. 1A. Consistent with the scope of the present disclosure, word line contact structure 234 can extend through both stack structures 222 and stack structure 226 in the vertical direction (the z-direction) and be in contact with both a conductive layer 219 in stack structure 222 and a conductive layer 229 in stack structure 226. In some implementations, word line contact structure 234 extends through staircase structure 242 of stack structure 226, semiconductor layer 224, and staircase structure 240 of stack structure 222 and is in contact with semiconductor layer 220 from top to bottom in the vertical direction (the z-direction). For example, word line contact structure 234 may include a first portion 234A extending through stack structure 222 and in contact with semiconductor layer 220, as well as a second portion 234B extending through stack structure 226 and semiconductor layer 224 and in contact with first portion 234A. Although not shown in FIG. 2A, it is understood that word line contact structure 234 may further include a bonding contact in contact with first portion 234A (as part of second semiconductor structure 204), and another bonding contact in contact with second portion 234B (as part of third semiconductor structure 206), which are in contact with one another. In other words, in some examples in which second and third semiconductor structures 204 and 206 are bonded together, first and second portions 234A and 234B of word line contact structure 234 may be formed by bonding using the bonding contacts. Word line contact structure 234 (including first and second portions 234A and 234B) can include conductive materials, including, but not limited to, W, Co, Cu, Al, polysilicon, doped silicon, silicides, or any combination thereof. For example, the conductive materials of first and second portions 234A and 234B may include W and/or TiN, and the conductive materials of the bonding contacts may include Cu.

In some implementations, besides conductive layer 219, first portion 234A of word line contact structure 234 is separated from the rest of conductive layers 221 in stack structure 222 by a spacer 236. That is, second semiconductor structure 204 can further include spacers 236 in staircase region 218 each extending in the vertical direction (the z-direction) and surrounding part of first portion 234A of word line contact structure 234 to electrically insulate first portion 234A of word line contact structure 234 from the rest of conductive layers 221 (except for conductive layer 219). Similarly, in some implementations, besides conductive layer 229, second portion 234B of word line contact structure 234 is separated from the rest of conductive layers 225 in stack structure 226 by a spacer 238. That is, third semiconductor structure 206 can further include spacers 236 in staircase region 218 each extending in the vertical direction (the z-direction) and surrounding part of second portion 234B of word line contact structure 234 to electrically insulate second portion 234B of word line contact structure 234 from the rest of conductive layers 225 (except for conductive layer 229). Spacers 236 and 238 can include dielectric materials including, but not limited to, silicon oxide, silicon nitride, silicon oxynitride, low-k dielectrics, or any combination thereof. For example, spacers 236 and 238 may include silicon oxide.

In some implementations, conductive layer 219 includes a first portion 219A in contact with first portion 234A of word line contact structure 234, and a second portion 219B not aligned with first portion 219A in the vertical direction (the z-direction). For example, second portion 219B of conductive layer 219 may be a word line/gate line, and first portion 219A of conductive layer 219 may be the “contact area” raised up from second portion 219B on the stair of staircase structure 240, as shown in FIG. 2A. In one example, second portion 219B of conductive layer 219 may include a gate line extending in the word line direction (the x-direction) and in contact with channel structure 228. Similarly, in some implementations, conductive layer 229 includes a first portion 229A in contact with second portion 234B of word line contact structure 234, and a second portion 229B not aligned with first portion 229A in the vertical direction (the z-direction). For example, second portion 229B of conductive layer 229 may be a word line/gate line, and first portion 229A of conductive layer 229 may be the “contact area” raised up from second portion 229B on the stair of staircase structure 242, as shown in FIG. 2A. In one example, second portion 229B of conductive layer 229 may include a gate line extending in the word line direction (the x-direction) and in contact with channel structure 230. In contrast, the rest of conductive layers 221 and 225 do not have portions that are raised up on the stairs of staircase structures 240 and 242 to be in contact with word line contact structure 234, according to some implementation. Also, spacers 236 and 238 do not extend to and cover parts of word line contact structure 234 at which first portions 219A and 229A of conductive layers 219 and 229 are formed, according to some implementations.

As described above, each word line contact structure can be electrically coupled to conductive layers (word lines/gate lines) in both stack structures 222 and 226. In some implementations, each of the conductive layers is at the same relative position in the vertical direction (the z-direction) in stack structures 222 and 226, respectively. For example, as shown in FIG. 2A, conductive layer 219 may be at the same relative position with respect to stack structure 222 as conductive layer 229 with respect to stack structure 226. Similarly, another word line contact structure may be in contact with two other conductive layers of stack structures 222 and 226, each of which may be at the same relative position (but different from conductive layers 219 and 229) in stack structures 226 and 226, respectively. In other words, different word line contact structures are electrically coupled to different sets of conductive layers, each of which is at the same relative position in the different stack structures, according to some implementations. As described above, conductive layers 219 and 229 can each include first portion 219A or 229A on a respective stair of staircase structure 240 or 242. In some implementations, the two stairs are at the same level with respect to staircase structures 240 or 242, respectively. Similarly, another word line contact structure may be in contact with first portions of two other conductive layers of stack structures 222 and 226, which may also be at the same level in staircase structures 240 and 242, respectively (but different from conductive layers 219 and 229).

Consistent with the scope of the present disclosure, 3D memory device 200 can further include select gate contact structures for select gate (SSG and/or DSG) lines pick-up/fan-out. As shown in FIG. 2B, 3D memory device 200 can further include select gate contact structures 252 and 254 in staircase region 218 of stack structures 222 and 226. Select gate contact structures 252 and 254 may be examples of LCT and UCT, respectively, in FIG. 1A. Different from word line contact structure 234, although select gate contact structures 252 and 254 can extend through both stack structures 222 and stack structure 226 in the vertical direction (the z-direction), each of select gate contact structures 252 and 254 can be in contact with only one respective conductive layer 239 or 249 in either stack structure 222 or 226. For example, select gate contact structure 252 may be in contact with a conductive layer 239 in stack structure 222 but separated from all conductive layers 225 in stack structure 226; select gate contact structure 254 may be in contact with a conductive layer 249 in stack structure 226 but separated from all conductive layers 221 in stack structure 222.

In some implementations, select gate contact structure 252 includes a first portion 252A extending through stack structure 222 and in contact with semiconductor layer 220, as well as a second portion 252B extending through stack structure 226 and semiconductor layer 224 and in contact with first portion 252A; select gate contact structure 254 includes a first portion 254A extending through stack structure 222 and in contact with semiconductor layer 220, as well as a second portion 254B extending through stack structure 226 and semiconductor layer 224 and in contact with first portion 254A. Although not shown in FIG. 2B, it is understood that select gate contact structure 252 or 254 may further include a bonding contact in contact with first portion 252A or 254A (as part of second semiconductor structure 204), and another bonding contact in contact with second portion 252B or 254B (as part of third semiconductor structure 206), which are in contact with one another. In other words, in some examples in which second and third semiconductor structures 204 and 206 are bonded together, first and second portions 252A and 252B of select gate contact structure 252 may be formed by bonding using the bonding contacts, and first and second portions 254A and 254B of select gate contact structure 254 may be formed by bonding using the bonding contacts. Select gate contact structures 252 and 254 (including first and second portions 252A, 252B, 254A, and 254B) can include conductive materials, including, but not limited to, W, Co, Cu, Al, polysilicon, doped silicon, silicides, or any combination thereof. For example, the conductive materials of first and second portions 252A, 252B, 254A, and 254B may include W and/or TiN, and the conductive materials of the bonding contacts may include Cu.

In some implementations, besides conductive layer 239, first portion 252A of select gate contact structure 252 is separated from the rest of conductive layers 221 in stack structure 222 by a spacer 260. That is, second semiconductor structure 204 can further include spacer 260 in staircase region 218 extending in the vertical direction (the z-direction) and surrounding part of first portion 252A of select gate contact structure 252 to electrically insulate first portion 252A of select gate contact structure 252 from the rest of conductive layers 221 (except for conductive layer 239). Different from word line contact structure 234, in some implementations, second portion 252B of select gate contact structure 252 is separated from all conductive layers 225 (including conductive layer 249) in stack structure 226 by a spacer 262. That is, third semiconductor structure 206 can further include spacer 262 in staircase region 218 extending in the vertical direction (the z-direction) and surrounding the entirety of second portion 252B of select gate contact structure 252 in stack structure 226 to electrically insulate second portion 252B of select gate contact structure 252 from all conductive layers 225 (including conductive layer 249).

In some implementations, besides conductive layer 249, second portion 254B of select gate contact structure 254 is separated from the rest of conductive layers 225 in stack structure 226 by a spacer 258. That is, third semiconductor structure 206 can further include spacer 258 in staircase region 218 extending in the vertical direction (the z-direction) and surrounding part of second portion 254B of select gate contact structure 254 to electrically insulate second portion 254B of select gate contact structure 254 from the rest of conductive layers 225 (except for conductive layer 249). Different from word line contact structure 234, in some implementations, first portion 254A of select gate contact structure 254 is separated from all conductive layers 221 (including conductive layer 239) in stack structure 222 by a spacer 256. That is, second semiconductor structure 204 can further include spacer 256 in staircase region 218 extending in the vertical direction (the z-direction) and surrounding the entirety of first portion 254A of select gate contact structure 254 in stack structure 222 to electrically insulate first portion 254A of select gate contact structure 254 from all conductive layers 221 (including conductive layer 239). Spacers 260, 262, 256, and 258 can include dielectric materials including, but not limited to, silicon oxide, silicon nitride, silicon oxynitride, low-k dielectrics, or any combination thereof. For example, spacers 260, 262, 256, and 258 may include silicon oxide.

In some implementations, conductive layer 239 includes a first portion 239A in contact with first portion 252A of select gate contact structure 252, and a second portion 239B not aligned with first portion 239A in the vertical direction (the z-direction). For example, second portion 239B of conductive layer 219 may be a DSG line or SSG line, and first portion 239A of conductive layer 239 may be the “contact area” raised up from second portion 239B on the stair of staircase structure 240, as shown in FIG. 2B. In one example, second portion 239B of conductive layer 239 may include a DSG line or SSG line extending in the word line direction (the x-direction) and in contact with channel structure 228. In some implementations, conductive layer 249 includes a first portion 249A in contact with second portion 254B of select gate contact structure 254, and a second portion 249B not aligned with first portion 249A in the vertical direction (the z-direction). For example, second portion 249B of conductive layer 249 may be a DSG line or SSG line, and first portion 249A of conductive layer 249 may be the “contact area” raised up from second portion 249B on the stair of staircase structure 242, as shown in FIG. 2B. In one example, second portion 249B of conductive layer 249 may include a DSG line or SSG line extending in the word line direction (the x-direction) and in contact with channel structure 230. In contrast, the rest of conductive layers 221 and 225 do not have portions that are raised up on the stairs of staircase structures 240 and 242 to be in contact with select gate contact structures 252 and 254, according to some implementation. Also, spacers 260 and 258 do not extend to and cover parts of select gate contact structures 252 and 254 at which first portions 239A and 249A of conductive layers 239 and 249 are formed, according to some implementations.

Different from a word line contact structure that is electrically coupled to conductive layers (word lines/gate lines) in both stack structures 222 and 226, each select gate contact structure can be electrically coupled to conductive layer(s) (DSG lines and/or SSG lines) of either stack structures 222 or stack structure 226, but not both. In some implementations, each of the conductive layers is at an end position in the vertical direction (the z-direction) of stack structures 222 and 226, respectively. In one example, the conductive layers are at the top position of stack structures 222 and 226, for example, including DSG lines. In another example, the conductive layers are at the bottom position of stack structures 222 and 226, for example, including SSG lines. For example, as shown in FIG. 2B, conductive layer 239 may be at the top end position of stack structure 222 and include a DSG line, and conductive layer 249 may be at the top end position of stack structure 226 and include a DSG line. Although not shown in FIG. 2B, it is understood that in some examples, each of stack structures 226 and 226 may include more than one DSG line, such that 3D memory device 200 may include additional set of select gate contact structures, similar to select gate contact structures 252 and 254, to drive the additional DSG line(s). It is also understood that although select gate contact structures 252 and 254 are electrically coupled to DSG lines in FIG. 2B, it is understood that in some examples, 3D memory device 200 may include select gate contact structures electrically coupled to SSG lines. As described above, conductive layers 239 and 249 can each include first portion 239A or 249A on a respective stair of staircase structure 240 or 242. In some implementations, the two stairs are at the same level with respect to staircase structures 240 or 242, respectively (e.g., the topmost level in FIG. 2B). It is understood that although not shown, in some examples, each additional set of select gate contact structures may be in contact with first portions of two other conductive layers of stack structures 222 and 226, which may also be at the same level of staircase structures 240 and 242, respectively (e.g., the second topmost level, the bottommost level, or the second bottommost level).

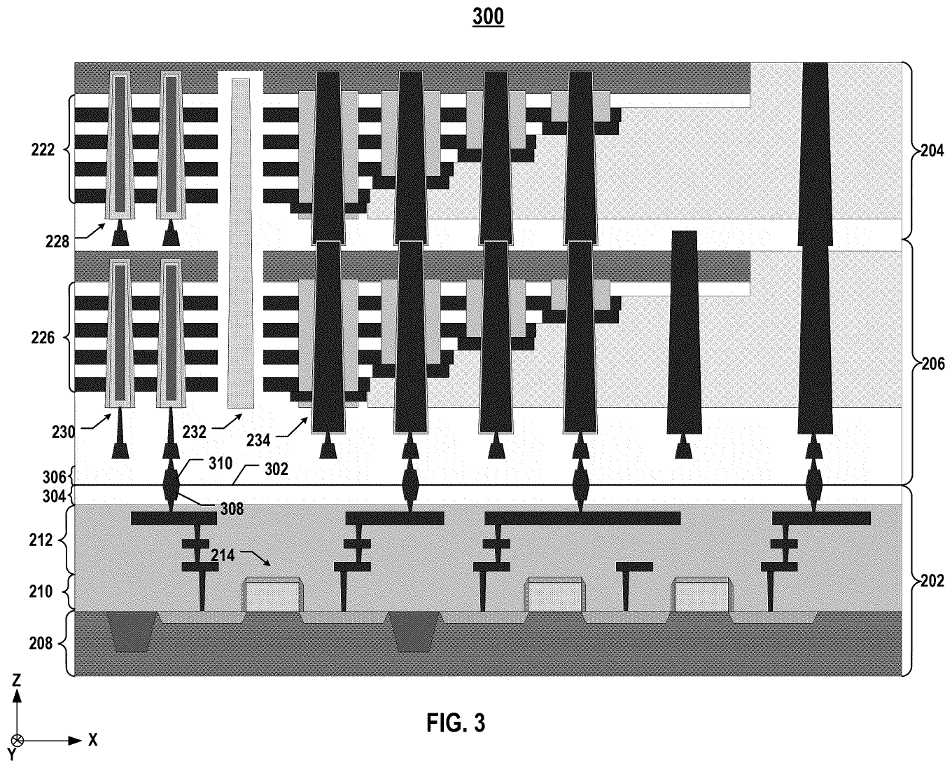

FIG. 3 illustrates a cross-sectional side view of another 3D memory device 300 having contact structures, according to some aspects of the present disclosure. As shown in FIG. 3, in 3D memory device 300, first semiconductor structure 202 can be bonded to second and third semiconductor structures 204 and 206 in a face-to-face manner at a bonding interface 302. It is understood that the details of the same components (e.g., materials, fabrication process, functions, etc.) in both 3D memory devices 300 and 200 are not repeated for ease of description.

As shown in FIG. 3, first semiconductor structure 202 can further include a bonding layer 304 at bonding interface 302 and above and in contact with interconnect layer 212. Bonding layer 304 can include a plurality of bonding contacts 308 and dielectrics electrically isolating bonding contacts 308. Bonding contacts 308 can include conductive materials including, but not limited to, W, Co, Cu, Al, silicides, or any combination thereof. In some implementations, bonding contacts 308 of bonding layer 304 include Cu. The remaining area of bonding layer 304 can be formed with dielectrics including, but not limited to, silicon oxide, silicon nitride, silicon oxynitride, low-k dielectrics, or any combination thereof. Bonding contacts 308 and surrounding dielectrics in bonding layer 304 can be used for hybrid bonding (also known as “metal/dielectric hybrid bonding”), which is a direct bonding technology (e.g., forming bonding between surfaces without using intermediate layers, such as solder or adhesives) and can obtain metal-metal (e.g., Cu-to-Cu) bonding and dielectric-dielectric (e.g., SiO₂-to-SiO₂) bonding simultaneously.

As shown in FIG. 3, third semiconductor structure 206 can further include a bonding layer 306 at bonding interface 302, e.g., on the opposite side of bonding interface 302 with respect to bonding layer 304 in first semiconductor structure 202. Bonding layer 306 can include a plurality of bonding contacts 310 and dielectrics electrically isolating bonding contacts 310. Bonding contacts 310 can include conductive materials, such as Cu. The remaining area of bonding layer 306 can be formed with dielectric materials, such as silicon oxide. Bonding contacts 310 and surrounding dielectrics in bonding layer 306 can be used for hybrid bonding. In some implementations, bonding contacts 308 are in contact with bonding contacts 310. In some implementations, bonding interface 302 is the place at which bonding layers 304 and 306 are met and bonded. In practice, bonding interface 302 can be a layer with a certain thickness that includes the top surface of bonding layer 304 of first semiconductor structure 202 and the bottom surface of bonding layer 306 of third semiconductor structure 206.

Although not shown in FIG. 3, it is understood that in some examples, second semiconductor structure 204 may be bonded with third semiconductor structure 206 using bonding contacts as well. For example, each of second semiconductor structure 204 and third semiconductor structure 206 may include respective bonding contacts between stack structure 222 and stack structure 226 in the vertical direction (the z-direction), and the bonding contacts in second semiconductor structure 204 may be in contact with the bonding contacts in third semiconductor structure 206.

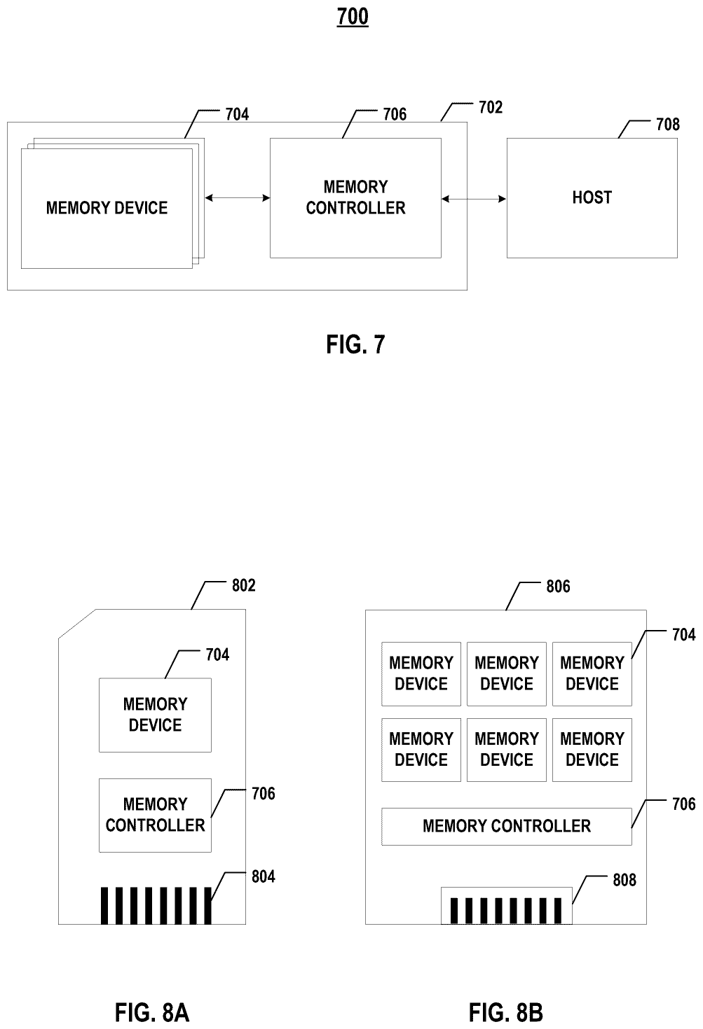

FIG. 7 illustrates a block diagram of an exemplary system 700 having a 3D memory device 704, according to some aspects of the present disclosure. System 700 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 7, system 700 can include a host 708 and a memory system 702 having one or more 3D memory devices 704 and a memory controller 706. Host 708 can be a processor of an electronic device, such as a central processing unit (CPU), or a system-on-chip (SoC), such as an application processor (AP). Host 708 can be configured to send or receive data to or from 3D memory devices 704.

3D memory device 704 can be any 3D memory device having contact structures disclosed herein, such as 3D memory devices 200 and 300 depicted in FIGS. 2A, 2B, and 3. In some implementations, each 3D memory device 704 includes a NAND Flash memory. Memory controller 706 (a.k.a., a controller circuit) is coupled to 3D memory device 704 and host 708 and is configured to control 3D memory device 704, according to some implementations. For example, memory controller 706 may be configured to operate the plurality of channel structures via the conductive layers (e.g., word lines/gate lines). Memory controller 706 can manage the data stored in 3D memory device 704 and communicate with host 708. In some implementations, memory controller 706 is designed for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some implementations, memory controller 706 is designed for operating in a high duty-cycle environment SSDs or embedded multi-media-cards (eMMCs) used as data storage for mobile devices, such as smartphones, tablets, laptop computers, etc., and enterprise storage arrays. Memory controller 706 can be configured to control operations of 3D memory device 704, such as read, erase, and program operations. Memory controller 706 can also be configured to manage various functions with respect to the data stored or to be stored in 3D memory device 704 including, but not limited to bad-block management, garbage collection, logical-to-physical address conversion, wear leveling, etc. In some implementations, memory controller 706 is further configured to process error correction codes (ECCs) with respect to the data read from or written to 3D memory device 704. Any other suitable functions may be performed by memory controller 706 as well, for example, formatting 3D memory device 704. Memory controller 706 can communicate with an external device (e.g., host 708) according to a particular communication protocol. For example, memory controller 706 may communicate with the external device through at least one of various interface protocols, such as a USB protocol, an MMC protocol, a peripheral component interconnection (PCI) protocol, a PCI-express (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

Memory controller 706 and one or more 3D memory devices 704 can be integrated into various types of storage devices, for example, be included in the same package, such as a universal Flash storage (UFS) package or an eMMC package. That is, memory system 702 can be implemented and packaged into different types of end electronic products. In one example as shown in FIG. 8A, memory controller 706 and a single 3D memory device 704 may be integrated into a memory card 802. Memory card 802 can include a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc. Memory card 802 can further include a memory card connector 804 electrically coupling memory card 802 with a host (e.g., host 708 in FIG. 7). In another example as shown in FIG. 8B, memory controller 706 and multiple 3D memory devices 704 may be integrated into an SSD 806. SSD 806 can further include an SSD connector 808 electrically coupling SSD 806 with a host (e.g., host 708 in FIG. 7). In some implementations, the storage capacity and/or the operation speed of SSD 806 is greater than those of memory card 802.

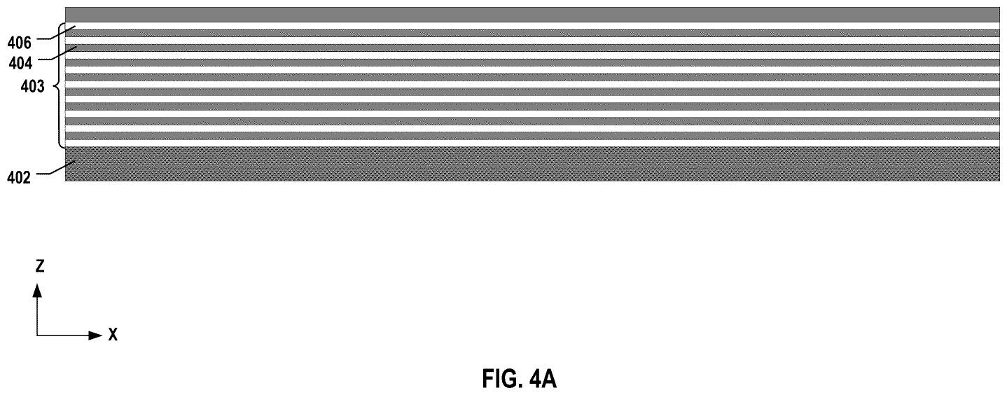

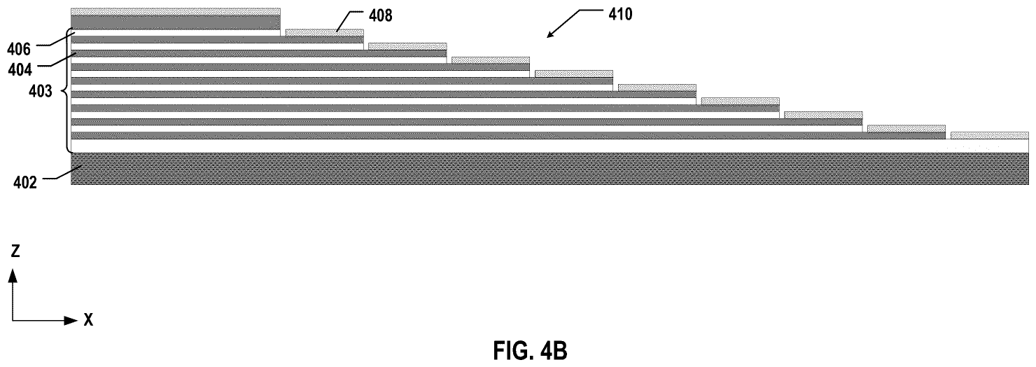

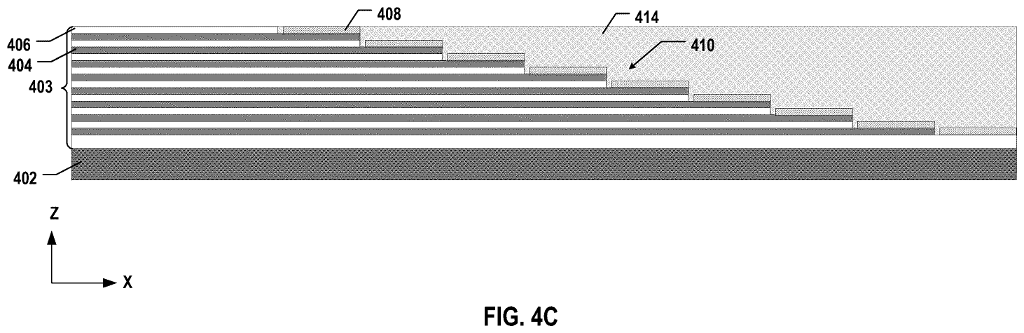

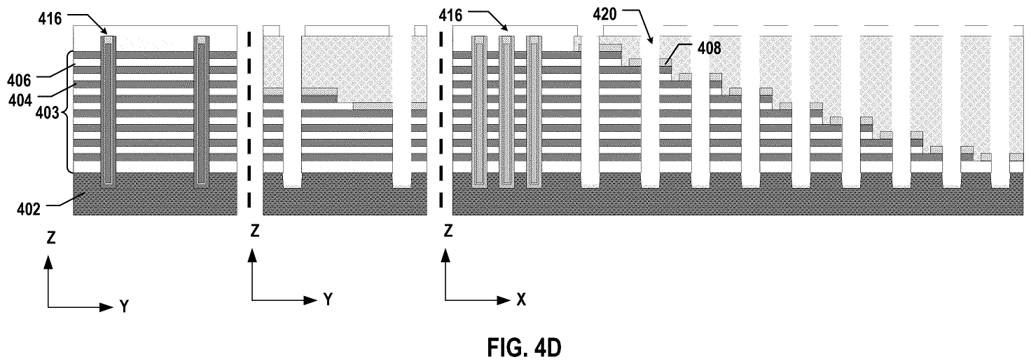

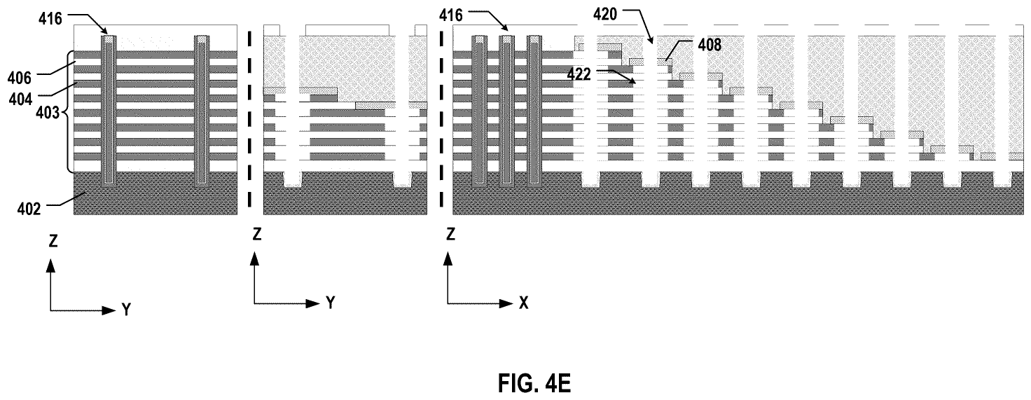

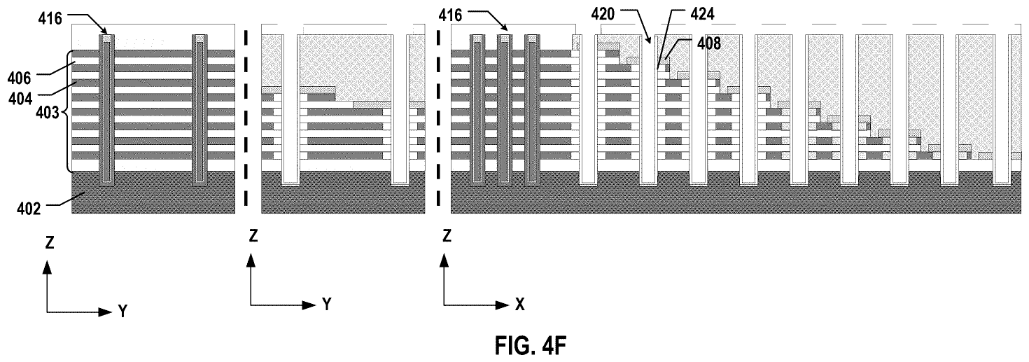

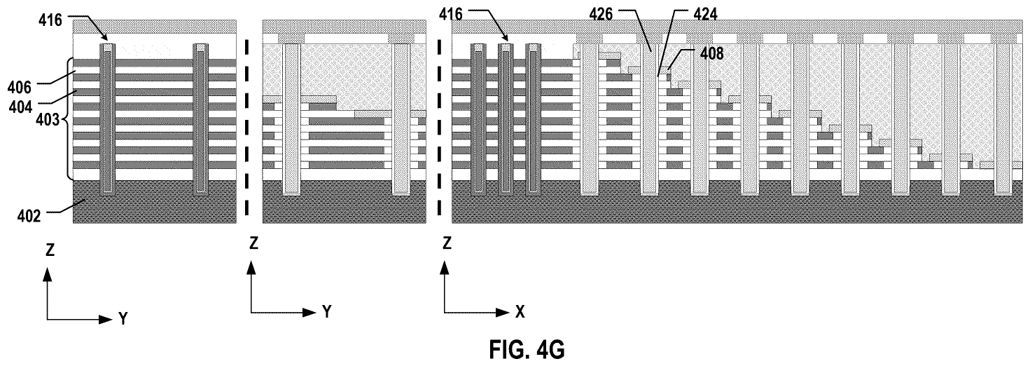

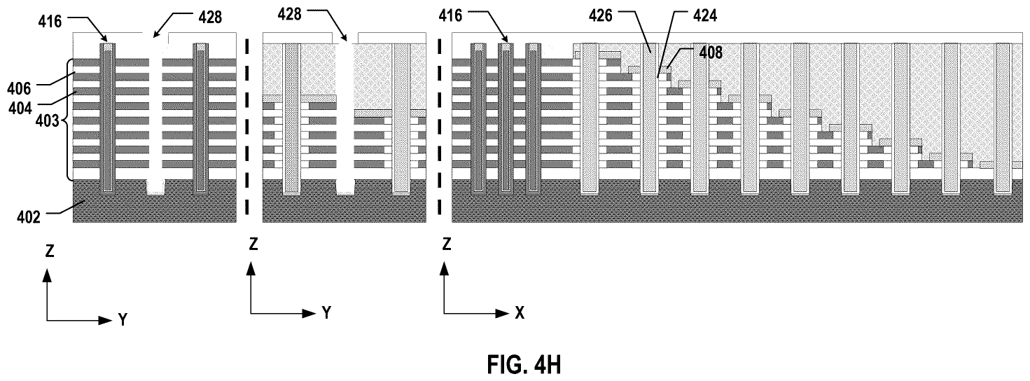

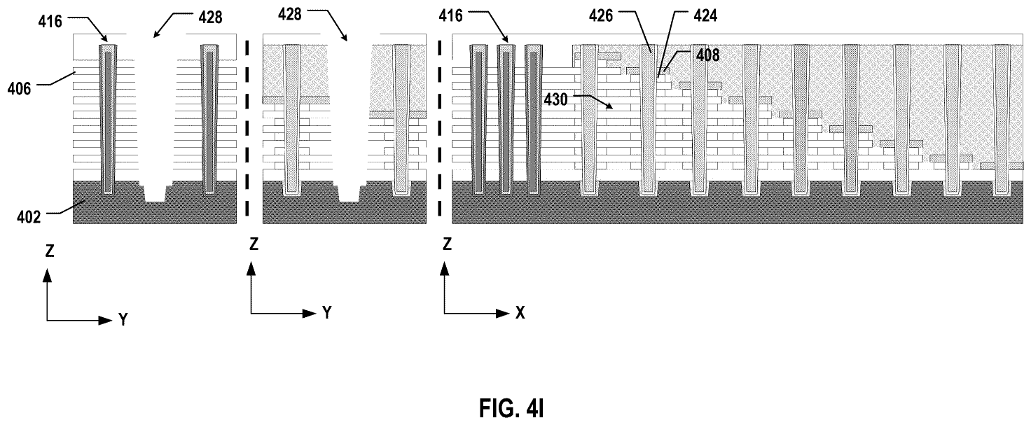

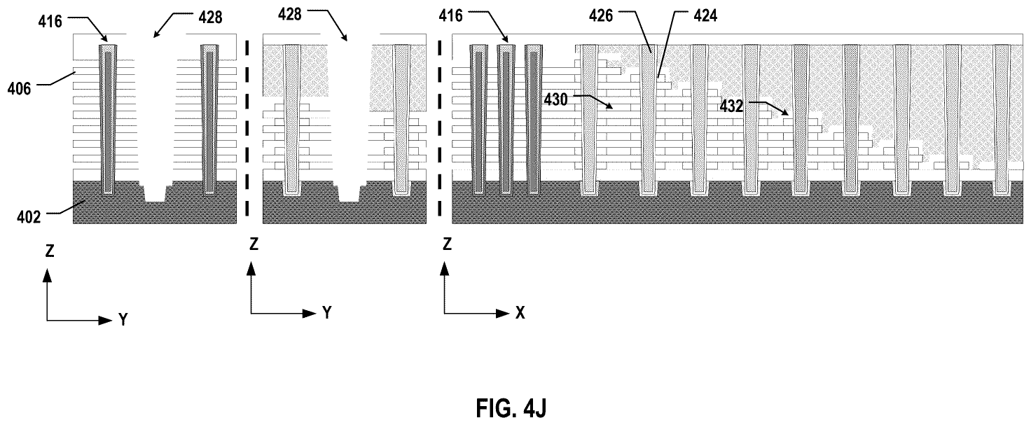

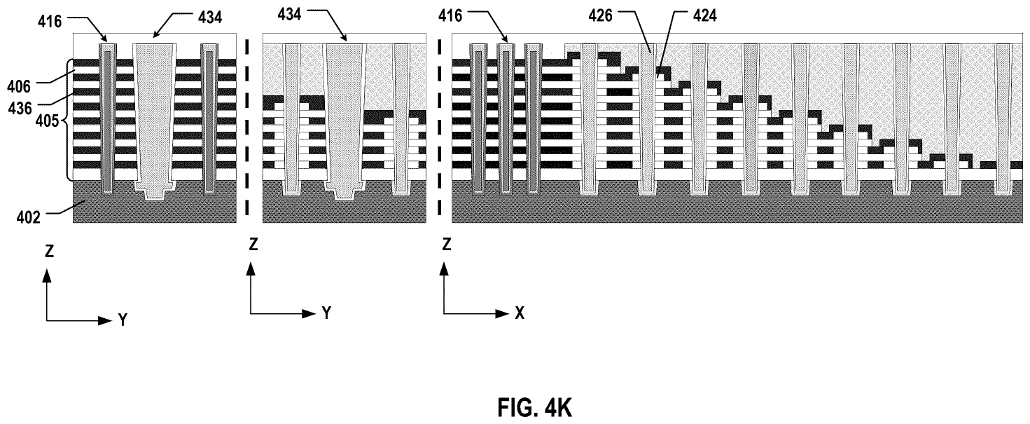

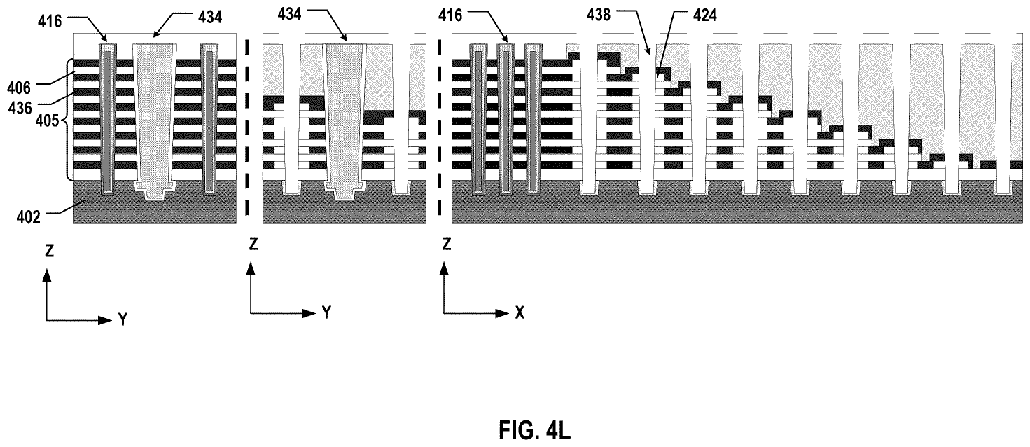

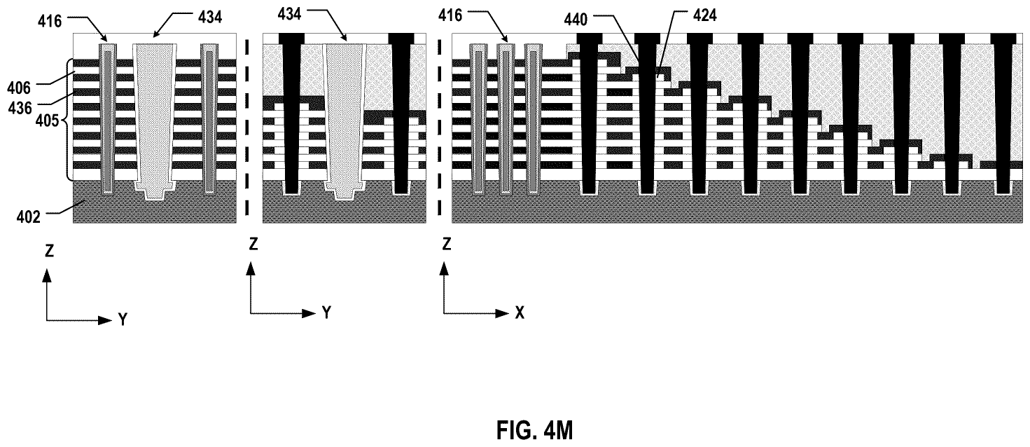

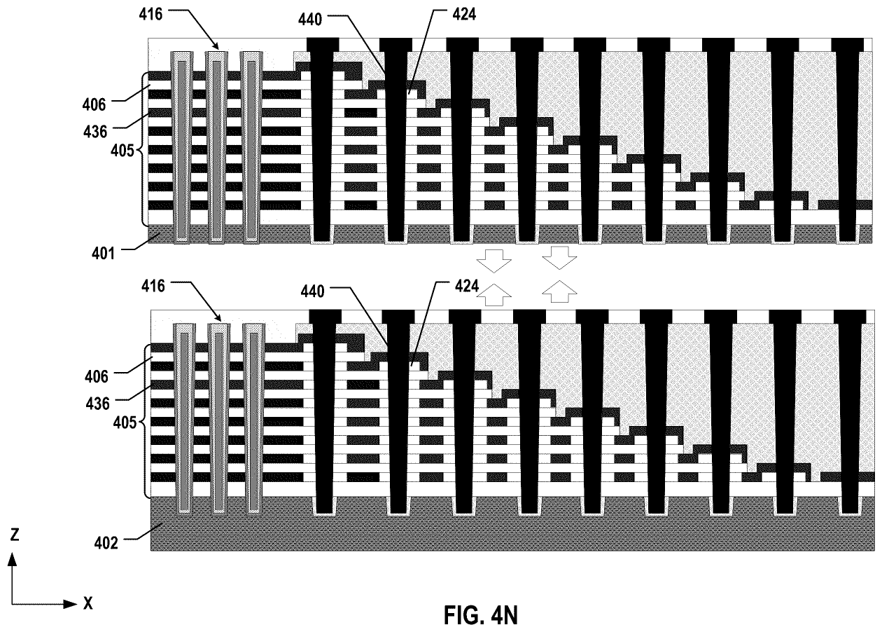

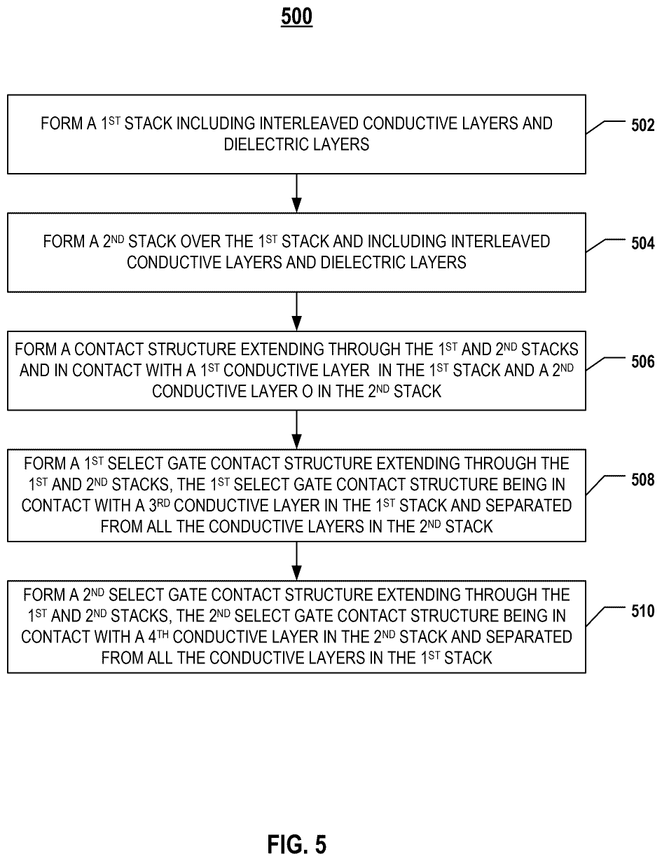

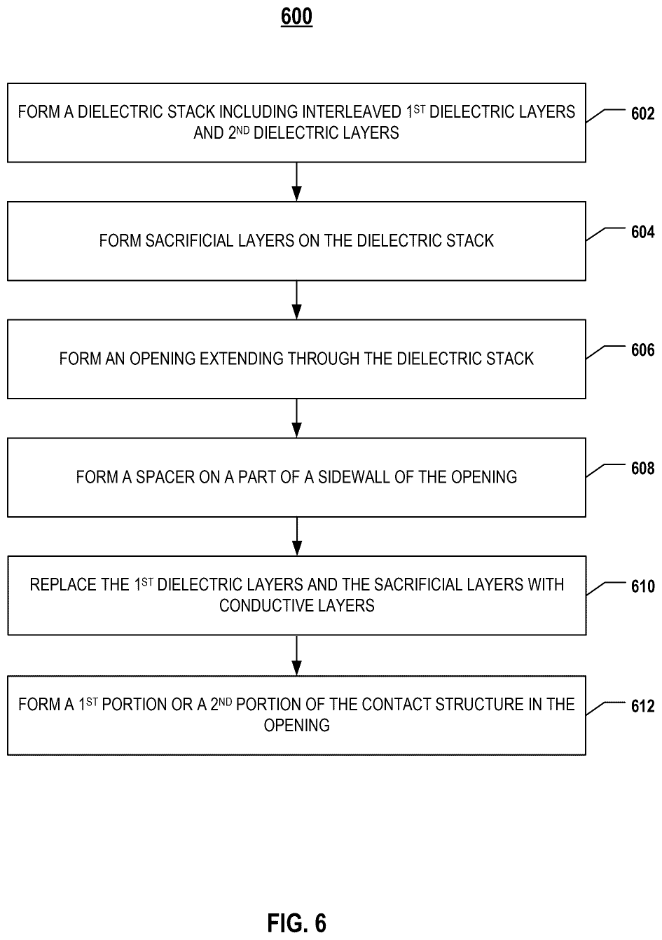

FIGS. 4A-4N illustrate a fabrication process for forming a 3D memory device having contact structures, according to some aspects of the present disclosure. FIG. 5 is a flowchart of a method 500 for forming a 3D memory device having contact structures, according to some aspects of the present disclosure. FIG. 6 is a flowchart of a method 600 for forming contact structures in a 3D memory device, according to some aspects of the present disclosure. Examples of the 3D memory device depicted in FIGS. 4A-4N, 5, and 6 include 3D memory devices 200 and 300 depicted in FIGS. 2A, 2B, and 3. FIGS. 4A-4N, 5, and 6 will be described together. It is understood that the operations shown in methods 500 and 600 are not exhaustive and that other operations can be performed as well before, after, or between any of the illustrated operations. Further, some of the operations may be performed simultaneously, or in a different order than shown in FIGS. 5 and 6.

Referring to FIG. 5, method 500 starts at operation 502, in which a first stack structure including interleaved conductive layers and dielectric layers is formed. Method 500 proceeds to operation 504, in which a second stack structure is formed over the first stack structure and includes interleaved conductive layers and dielectric layers. Method 500 proceeds to operation 506, in which a contact structure extending through the first stack structure and the second stack structure and in contact with a first conductive layer of the conductive layers in the first stack structure and a second conductive layer of the conductive layers in the second stack structure is formed.

To form the contact structure, a first portion of the contact structure extending through the first stack structure and in contact with the first conductive layer in the first stack structure is formed, and a second portion of the contact structure extending through the second stack structure and in contact with the second conductive layer in the second stack structure and the first portion of the contact structure is formed, according to some implementation. In some implementations, the first portion or the second portion of the contact structure is formed in contact with only one of the conductive layers. For example, FIG. 6 is a flowchart of method 600 for forming the contact structure, according to some aspects of the present disclosure.

Referring to FIG. 6, method 600 starts at operation 602, in which a dielectric stack including interleaved first dielectric layers and second dielectric layers is formed. The first dielectric layers can include silicon oxide, and the second dielectric layers can include silicon nitride. In some implementations, to form the dielectric stack, the first dielectric layers and the second dielectric layers are alternatingly deposited above a substrate. The substrate can be a silicon substrate.

As illustrated in FIG. 4A, a dielectric stack 403 including multiple pairs of a first dielectric layer 406 and a second dielectric layer 404 (a.k.a., a stack sacrificial layer) is formed above a silicon substrate 402. Dielectric stack 403 includes vertically interleaved first dielectric layers 406 and second dielectric layers 404, according to some implementations. First and second dielectric layers 406 and 404 can be alternatingly deposited above silicon substrate 402 to form dielectric stack 403. In some implementations, each first dielectric layer 406 includes a layer of silicon oxide, and each second dielectric layer 404 includes a layer of silicon nitride. Dielectric stack 403 can be formed by one or more thin film deposition processes including, but not limited to, chemical vapor deposition (CVD), physical vapor deposition (PVD), atomic layer deposition (ALD), or any combination thereof.

Method 600 proceeds to operation 604, as illustrated in FIG. 6, in which sacrificial layers are formed on the dielectric stack. In some implementations, to form the sacrificial layers, a staircase structure including stairs is formed in the dielectric stack, and the sacrificial layers are formed on a topmost layer of each stair of the staircase structure.

As illustrated in FIG. 4B, a staircase structure 410 having a plurality of stairs is formed in a staircase region of dielectric stack 403, which can be either in the intermediate or on two sides of dielectric stack 403. Staircase structure 410 can be formed by performing a plurality of so-called “trim-etch” cycles to the pairs of first dielectric layer 406 and second dielectric layer 404 of dielectric stack 403 toward silicon substrate 402. Due to the repeated trim-etch cycles applied to the pairs of first dielectric layer 406 and second dielectric layer 404, dielectric stack 403 can have one or more tilted edges, and an upper pair of first dielectric layer 406 and second dielectric layer 404 is shorter than the lower one as shown in FIG. 4B.

As illustrated in FIG. 4B, sacrificial layers 408 are each formed on a respective topmost layer of each stair in staircase structure 410, for example, the exposed second dielectric layer 404 at each stair. Sacrificial layers 408 can have materials different from those of second dielectric layers 404, such as polysilicon. To form sacrificial layers 408, a sacrificial material, such as polysilicon, can be deposited on staircase structure 410 using one or more thin film deposition processes, such as CVD, PVD, ALD, or any combination thereof. The deposited material can then be aligned and patterned using lithography and dry etching and/or wet etching to form sacrificial layers 408 on the topmost layer of each stair of staircase structure 410.

As illustrated in FIG. 4C, an insulating layer 414 is formed on dielectric stack 403 to cover staircase structure 410. In some implementations, a dielectric material, such as silicon oxide, is deposited on dielectric stack 403 and sacrificial layers 408, covering staircase structure 410 using one or more thin film deposition processes, such as CVD, PVD, ALD, or any combination thereof, to form insulating layer 414. In some implementations, the excess sacrificial layers 408 and insulating layer 414 are removed using a planarization process, such as chemical mechanical polishing (CMP).

In some implementations, channel structures extending through the first dielectric layers and the second dielectric layers are formed in a memory array region of the dielectric stack. In some implementations, to form the channel structure, a channel hole extending vertically through the dielectric stack is formed, and a memory layer and a channel layer are sequentially formed over the sidewalls of the channel hole.

FIG. 4D illustrates the side view of dielectric stack 403 along the word line direction (the x-direction) in the right part of FIG. 4D. FIG. 4D also illustrates the side view of the memory cell region of dielectric stack 403 along the bit line direction (the y-direction) in the left part of FIG. 4D, as well as the side view of the staircase region of dielectric stack 403 along the bit line direction (the y-direction) in the middle part of FIG. 4D. The same manner of illustration is applied to FIGS. 4E-4M as well.

As illustrated in the left part of FIG. 4D, channel structures 416 are formed in the memory array region of dielectric stack 403. To form each channel structure 416, a channel hole, which is an opening extending through dielectric stack 403 in the vertical direction (the z-direction) until silicon substrate 402, can be formed first in the memory array region of dielectric stack 403. In some implementations, a plurality of openings are formed, such that each opening becomes the location for forming an individual channel structure 416 in the later process. In some implementations, fabrication processes for forming the channel hole of channel structure 416 include wet etching and/or dry etching, such as deep-ion reactive etching (DRIE). A memory layer (including a blocking layer, a storage layer, and a tunneling layer) and a channel layer can then be sequentially formed in this order along sidewalls and the bottom surface of the channel hole. In some implementations, the memory layer is first deposited along the sidewalls and bottom surface of the channel hole, and the semiconductor channel is then deposited over the memory layer. The blocking layer, storage layer, and tunneling layer can be subsequently deposited in this order using one or more thin film deposition processes, such as ALD, CVD, PVD, any other suitable processes, or any combination thereof, to form the memory layer. The channel layer can then be formed by depositing a semiconductor material, such as polysilicon, over the tunneling layer of the memory layer using one or more thin film deposition processes, such as ALD, CVD, PVD, any other suitable processes, or any combination thereof. In some implementations, a first silicon oxide layer, a silicon nitride layer, a second silicon oxide layer, and a polysilicon layer (a “SONO” structure) are subsequently deposited to form the memory layer and the channel layer of channel structure 416.

Method 600 proceeds to operation 606, as illustrated in FIG. 6, in which an opening extending through the dielectric stack is formed. As illustrated in the middle and right parts of FIG. 4D, openings 420 of word line contact structures are formed in the staircase region of dielectric stack 403, each of which extends through dielectric stack 403 in the vertical direction (the z-direction) until silicon substrate 402. Each opening 420 can become the location for forming an individual word line contact structure in the later process. In some implementations, fabrication processes for forming openings 420 include wet etching and/or dry etching, such as DRIE.

Method 600 proceeds to operation 608, as illustrated in FIG. 6, in which a spacer is formed on a part of a sidewall of the opening. As illustrated in the middle and right parts of FIG. 4E, lateral recesses 422 are formed by etching back second dielectric layers 404 through openings 420, for example, using wet etching. As illustrated in the middle and right parts of FIG. 4F, a spacer 424 is formed on the sidewall of each opening 420. In some implementations, spacer 424 is formed by depositing a dielectric material, such as the same dielectric material as first dielectric layers 406 (e.g., silicon oxide) to fill lateral recesses 422 (as shown in FIG. 4E) and on the sidewall of opening 420 using one or more thin film deposition processes, such as ALD, CVD, PVD, any other suitable processes, or any combination thereof. In some implementations, the deposition rate and/or time is controlled, such that the dielectric material does not fully fill opening 420, for example, by using ALD. As illustrated in the middle and right parts of FIG. 4G, the remainder of opening 420 (as shown in FIG. 4F) is filled with a sacrificial layer 426 to cover and protect spacer 424 during the later process. In some implementations, sacrificial layer 426 is formed by depositing polysilicon to fill opening 420 using one or more thin film deposition processes, such as ALD, CVD, PVD, any other suitable processes, or any combination thereof.

Method 600 proceeds to operation 610, as illustrated in FIG. 6, in which the second dielectric layers and the sacrificial layers are replaced with conductive layers, for example, by a gate replacement process. The conductive layers can include a metal, such as tungsten. In some implementations, to replace the second dielectric layers and the sacrificial layers with the conductive layers, a slit extending through the first dielectric layers and the second dielectric layers and across the memory array region and the staircase region of the dielectric stack is formed, the second dielectric layers and the sacrificial layers are removed from the slit, and the with conductive layers are formed through the slit.

As illustrated in the left and middle parts of FIG. 4H, a slit 428 is an opening that extends through first dielectric layers 406 and second dielectric layers 404 of dielectric stack 403 in the vertical direction (the z-direction) until silicon substrate 402. Slit 428 can also extend laterally across the memory array region and the staircase region in the word line direction (the x-direction). In some implementations, fabrication processes for forming slit 428 include wet etching and/or dry etching, such as DRIE, of first dielectric layers 406 and second dielectric layers 404. The etching process through dielectric stack 403 may not stop at the top surface of silicon substrate 402 and may continue to etch part of silicon substrate 402 to ensure that slit 428 extends vertically all the way through all first dielectric layers 406 and second dielectric layers 404 of dielectric stack 403.

As illustrated in FIG. 4I, second dielectric layers 404 (as shown in FIG. 4H) are removed by wet etching to form lateral recesses 430. In some implementations, second dielectric layers 404 are wet etched by applying a wet etchant through slit 428, creating lateral recesses 430 interleaved between first dielectric layers 406. The wet etchant can include phosphoric acid for etching second dielectric layers 404 including silicon nitride.

As illustrated in FIG. 4J, sacrificial layers 408 (as shown in FIG. 4I) are removed by wet etching to form lateral recesses 432. In some implementations, sacrificial layers 408 are wet etched by applying a wet etchant through slit 428 and lateral recesses 430, creating lateral recesses 432 surrounding spacers 424 and sacrificial layers 426. The wet etchant can include potassium hydroxide (KOH) for etching sacrificial layer 408 having polysilicon. Since sacrificial layers 408 are formed on top of second dielectric layers 404, as shown in FIG. 4B, lateral recesses 430 and lateral recesses 432 are not aligned in the vertical direction (the z-direction), according to some implementations. For example, as shown in FIG. 4J, lateral recess 432 may be raised up from corresponding lateral recess 430 that is at the same level as lateral recess 432.

As illustrated in FIG. 4K, conductive layers 436 are deposited into lateral recesses 430 and 432 through slit 428 (as shown in FIG. 4J). Conductive layers 436, such as metal layers (e.g., W and TiN), can be deposited to fill lateral recesses 430 and 432 using one or more thin film deposition processes, such as ALD, CVD, PVD, any other suitable processes, or any combination thereof. As a result, second dielectric layers 404 and sacrificial layers 408 are replaced with conductive layers 436, and dielectric stack 403 is replaced with a memory stack 405 including interleaved first dielectric layers 406 and conductive layers 436, according to some implementation. As shown in FIG. 4K, for each conductive layer 436, the part that is replaced from sacrificial layer 408 is not aligned with, e.g., raised up from, the other part that is replaced from second dielectric layer 404 in the vertical direction (the z-direction), according to some implementations.

As illustrated in the left and middle parts of FIG. 4K, a slit structure 434 extending vertically through interleaved conductive layers 436 and first dielectric layers 406 of memory stack 405 and laterally across the memory array region and staircase region is formed in slit 428 (as shown in FIG. 4J). Slit structure 434 can be formed by depositing dielectric materials, such as silicon oxide, into slit 428 using one or more thin film deposition processes, such as ALD, CVD, PVD, any other suitable processes, or any combination thereof. In some implementations, conductive materials, such as W and TiN (as a source interconnect), are deposited into slit 428 after depositing the dielectric materials, as part of slit structure 434.

Method 600 proceeds to operation 612, as illustrated in FIG. 6, in which a first portion or a second portion of the contact structure is formed in the opening. In some implementations, the first portion or the second portion of the contact structure is formed in contact with only one of the conductive layers. In some implementations, a semiconductor layer is formed over the first stack structure, and the second stack structure is formed over the semiconductor layer. In some implementations, the contact structure extends through the first stack structure, the semiconductor layer, and the second stack structure.

As illustrated in the middle and right parts of FIG. 4L, sacrificial layers 426 (as shown in FIG. 4K) filled in openings 438 are removed, exposing openings 438 again. Sacrificial layers 426 can be removed using wet etching and/or drying etching, such as DRIE. As illustrated in middle and right parts of FIG. 4L, spacers 424 are etched back from openings 438 to expose the parts of conductive layers 436 that are replaced from sacrificial layers 408 (the raised-up parts). Spacers 424 can be etched back using wet etching and/or drying etching to partially remove spacers 424 from openings 438. The etching rate and/or time can be controlled, such that the parts of conductive layers 436 that are replaced from sacrificial layers 408 (the raised-up parts) are exposed after etching back, while the other parts of conductive layers 436 that are replaced from second dielectric layers 404 are still covered and insulated by spacers 424, as shown in FIG. 4L.

As illustrated in the middle and right parts of FIG. 4M, a portion of word line contact structure 440 is formed in each opening 438 (as shown in FIG. 4M) in contact with only one of conductive layers 436. Word line contact structures 440, such as metal layers (e.g., W and TiN), can be deposited to fill openings 438 using one or more thin film deposition processes, such as ALD, CVD, PVD, any other suitable processes, or any combination thereof. As a result, a portion of word line contact structure 440 becomes in contact with one of conductive layers 436, e.g., the part of conductive layers 436 that is replaced from sacrificial layers 408 (the raised-up part), while separated from the rest of conductive layers 436 by spacers 424.

As illustrated FIG. 4N, in some implementations, silicon substrate 402 is thinned, for example, using etching and/or CMP to form a semiconductor layer 401 and expose the bottom of portions of word line contact structures 440. In some implementations, operations 602-612 are repeated to form another semiconductor structure, such that the two semiconductor structures can be bonded together using any suitable bonding methods, such as hybrid bonding, anodic bonding, etc. As a result, semiconductor layer 401 can be formed over memory stack 405 of another semiconductor structure, and two portions of word line contact structures 440 from the two semiconductor structures can be in contact with one another to form a word line contact structure 440, which extends through memory stacks 405 of the two semiconductor structures and semiconductor layer 401 in the vertical direction (the z-direction).

Although not shown, it is understood that in some examples, a semiconductor layer may be formed on top of the semiconductor structure that is formed after operation 612. To form the semiconductor layer, polysilicon can be deposited using one or more thin film deposition processes, such as ALD, CVD, PVD, any other suitable processes, or any combination thereof. In some implementations, operations 602-612 are repeated to form another semiconductor structure on the semiconductor layer. As a result, the semiconductor layer can be formed over memory stack 405 of another semiconductor structure, and two portions of word line contact structures 440 from the two semiconductor structures can be in contact with one another to form a word line contact structure 440, which extends through memory stacks 405 of the two semiconductor structures and the semiconductor layer in the vertical direction (the z-direction).

Referring back to FIG. 5, method 500 proceeds to operation 508, in which a first select gate contact structure extending through the first stack structure and the second stack structure is formed. In some implementations, the first select gate contact structure is in contact with a third conductive layer of the conductive layers in the first stack structure and is separated from all the conductive layers in the second stack structure. Method 500 proceeds to operation 510, in which a second select gate contact structure extending through the first stack structure and the second stack structure is formed. In some implementations, the second select gate contact structure is in contact with a fourth conductive layer of the conductive layers in the second stack structure and separated from all the conductive layers in the first stack structure. To form the first and second select gate contact structures, in some implementations, a first portion of the first select gate contact structure extending through the first stack structure and in contact with the third conductive layer in the first stack structure is formed, and a first portion of the second select gate contact structure extending through the first stack structure and separated from all the conductive layers in the first stack structure is formed. To form the first and second select gate contact structures, in some implementations, a second portion of the first select gate contact structure extending through the second stack structure and separated from all the conductive layers in the second stack structure, is formed, and a second portion of the second select gate contact structure extending through the second stack structure and in contact with the fourth conductive layer in the second stack structure is formed. Although not shown, it is understood that select gate contact structures (e.g., select gate contact structures 252 and 254 in FIG. 2B) may be formed using similar operations for forming word line contact structures 440 in method 600.

The foregoing description of the specific implementations can be readily modified and/or adapted for various applications. Therefore, such adaptations and modifications are intended to be within the meaning and range of equivalents of the disclosed implementations, based on the teaching and guidance presented herein.

The breadth and scope of the present disclosure should not be limited by any of the above-described exemplary implementations, but should be defined only in accordance with the following claims and their equivalents.

What is claimed is:

1. A three-dimensional (3D) memory device, comprising:
a first stack structure comprising interleaved conductive layers and dielectric layers;
a second stack structure over the first stack structure in a first direction and comprising interleaved conductive layers and dielectric layers; and
a contact structure extending through the first stack structure and the second stack structure in the first direction and in contact with a first conductive layer of the conductive layers in the first stack structure and a second conductive layer of the conductive layers in the second stack structure.

2. The 3D memory device of claim 1, wherein each of the first conductive layer and the second conductive layer is at a same relative position in the first direction in the first stack structure and the second stack structure, respectively.

3. The 3D memory device of claim 1, wherein each of the first conductive layer and the second conductive layer comprises a first portion in contact with the contact structure and a second portion not aligned with the first portion in the first direction.

4. The 3D memory device of claim 1, wherein the contact structure is separated from the rest of the conductive layers in the first stack structure by a first spacer extending in the first direction and separated from the rest of the conductive layers in the second stack structure by a second spacer extending in the first direction.

5. The 3D memory device of claim 1, further comprising:
a first select gate contact structure extending through the first stack structure and the second stack structure in the first direction, wherein the first select gate contact structure is in contact with a third conductive layer of the conductive layers in the first stack structure and separated from all the conductive layers in the second stack structure; and
a second select gate contact structure extending through the first stack structure and the second stack structure in the first direction, wherein the second select gate contact structure is in contact with a fourth conductive layer of the conductive layers in the second stack structure and separated from all the conductive layers in the first stack structure.

6. The 3D memory device of claim 5, wherein the third conductive layer is at an end position in the first direction in the first stack structure, and the fourth conductive layer is at an end position in the first direction in the second stack structure.

7. The 3D memory device of claim 5, wherein the contact structure, the first select gate contact structure, and the second select gate contact structure are disposed in a staircase region of the first stack structure and the second stack structure.

8. The 3D memory device of claim 7, wherein
the first stack structure comprises a first staircase structure comprising a first stair in the staircase region;
the second stack structure comprises a second staircase structure comprising a second stair in the staircase region; and
the contact structure is in contact with part of the first conductive layer at the first stair and part of the second conductive layer at the second stair, the first and second stairs being at a same level with respect to the first and second staircase structures, respectively.

9. The 3D memory device of claim 7, wherein
the first stack structure comprises a first staircase structure comprising a third stair in the staircase region;
the second stack structure comprises a second staircase structure comprising a fourth stair in the staircase region;
the first select gate contact structure is in contact with part of the third conductive layer at the third stair; and
the second select gate contact structure is in contact with part of the fourth conductive layer at the fourth stair, the third and fourth stairs being at a same level with respect to the first and second staircase structures, respectively.

10. The 3D memory device of claim 1, further comprising:
a first semiconductor layer;
a second semiconductor layer between the first stack structure and the second stack structure in the first direction;
a first channel structure extending through the first stack structure in the first direction and in contact with the first semiconductor layer; and
a second channel structure extending through the second stack structure in the first direction and in contact with the second semiconductor layer.

11. The 3D memory device of claim 10, wherein the contact structure comprises a first portion extending through the first stack structure and in contact with the first conductive layer, and a second portion extending through the second stack structure and the second semiconductor layer and in contact with the second conductive layer.

12. The 3D memory device of claim 10, further comprising:
a first bit line extending in a second direction perpendicular to the first direction and in contact with the first channel structure; and
a second bit line extending in the second direction and in contact with the second channel structure,
wherein the first conductive layer extends in a third direction perpendicular to the first and second directions and is in contact with the first channel structure; and
the second conductive layer extends in the third direction and is in contact with the second channel structure.

13. The 3D memory device of claim 1, further comprising a first bonding contact and a second bonding contact, wherein the first bonding contact and the second bonding contact are between the first stack structure and the second stack structure in the first direction and in contact with one another.

14. The 3D memory device of claim 1, wherein the contact structure comprises a third bonding contact and a fourth bonding contact in contact with one another.

15. A method for forming a three-dimensional (3D) memory device, comprising:
forming a first stack structure comprising interleaved conductive layers and dielectric layers;
forming a second stack structure over the first stack structure and comprising interleaved conductive layers and dielectric layers; and
forming a contact structure extending through the first stack structure and the second stack structure and in contact with a first conductive layer of the conductive layers in the first stack structure and a second conductive layer of the conductive layers in the second stack structure.

16. The method of claim 15, wherein forming the contact structure comprises:
forming a first portion of the contact structure extending through the first stack structure and in contact with the first conductive layer in the first stack structure; and
forming a second portion of the contact structure extending through the second stack structure and in contact with the second conductive layer in the second stack structure, wherein the second portion of the contact structure is in contact with the first portion of the contact structure.

17. The method of claim 16, wherein forming the first portion or the second portion of the contact structure comprises:
forming a dielectric stack comprising interleaved first dielectric layers and second dielectric layers;
forming sacrificial layers on the dielectric stack;
forming an opening extending through the dielectric stack;
replacing the second dielectric layers and the sacrificial layers with conductive layers; and
forming the first portion or the second portion of the contact structure in the opening.

18. The method of claim 17, further comprising forming a spacer on a part of a sidewall of the opening, wherein the first portion or the second portion of the contact structure is formed in contact with only one of the conductive layers.

19. The method of claim 15, further comprising:
forming a first select gate contact structure extending through the first stack structure and the second stack structure, wherein the first select gate contact structure is in contact with a third conductive layer of the conductive layers in the first stack structure and separated from all the conductive layers in the second stack structure; and
forming a second select gate contact structure extending through the first stack structure and the second stack structure, wherein the second select gate contact structure is in contact with a fourth conductive layer of the conductive layers in the second stack structure and separated from all the conductive layers in the first stack structure.

20. A memory device, comprising:
an array of memory cells arranged in a first block and a second block;
a first source line coupled to the first block, and a second source line coupled to the second block;
a first bit line coupled to the first block, and a second bit line coupled to the second block;
a first word line coupled to the first block, and a second word line coupled to the second block, wherein the first word line is coupled to the second word line;
a first select gate line coupled to the first block, and a second select gate line coupled to the second block; and
peripheral circuits configured to operate the array of memory cells, comprising:
a same word line string driver coupled to the first block and the second block through the first word line and the second word line;
a first select gate string driver coupled to the first block through the first select gate line; and
a second select gate string driver coupled to the second block through the second select gate line.
